(19) United States
(12) Patent Application Publication
(10) Pub. No.: US 2010/0046566 A1
(43) Pub. Date: Feb. 25, 2010

(54) SEMICONDUCTOR LIGHT EMITTING DEVICE AND METHOD FOR MANUFACTURING THE SAME

(76) Inventor: Akiyoshi KUDO, Hyogo (JP)

Correspondence Address: MCDERMOTT WILL & EMERY LLP, 600 13TH STREET, NW, WASHINGTON, DC, 20005-3096, US

(21) Appl. No.: 12/474,834

(22) Filed: May 29, 2009

(30) Foreign Application Priority Data
Aug. 21, 2008 (JP) 2008-212767

(51) Int. Cl. H01S 5/22; H01L 21/00

(52) U.S. Cl. 372/45.01; 438/39; 257/E21.002

(57) ABSTRACT

A semiconductor light emitting device includes at least a first cladding layer of a first conductive type, an active layer, a second cladding layer of a second conductivity type, and a contact layer of the second conductivity type stacked in this order on a substrate, and further includes a ridge portion including the second cladding layer and the contact layer. On the second cladding layer, are formed a dielectric film which covers the ridge portion and has an opening selectively exposing a top of the ridge portion, and an electrode in contact with a top surface and a side surface of the contact layer exposed from the dielectric film. The dielectric film includes a no-current injection region which covers an end of the ridge portion to block current injection to the active layer, and the no-current injection region of the dielectric film is in contact with the contact layer.

### CROSS-REFERENCE TO RELATED APPLICATION

This application claims priority from Japanese Patent Application No. 2008-212767 filed on Aug. 21, 2008, the disclosure of which application is hereby incorporated by reference in its entirety for all purposes.

### BACKGROUND

The present disclosure relates generally to a semiconductor light emitting device and a method for manufacturing the same. In particular, it relates to a gallium nitride (GaN)-based semiconductor laser diode having a no-current injection region and a method for manufacturing the same.

In recent years, light emitting devices using a gallium nitride (GaN)-based semiconductor have rapidly become popular as laser diodes or light emitting diodes. In particular, GaN-based semiconductor laser diodes are considered as a key device for optical pickup devices in high density optical disc systems, and are becoming of great importance in an industrial field. In response to increase in the use of them, high-power and long-life light emitting devices which allow size reduction and reduction in operating current have been demanded.

Especially for high power operation, demanded are a technique of reducing the operating current, a technique of stabilizing a lateral mode of laser light, and a technique of preventing optical damage (Catastrophic Optical Damage: COD) of a cavity. In order to suppress the optical damage, for example, Published Japanese Patent Application No. 2008-34587 describes a structure including a no-current injection region near an end face of a cavity. Consideration has been given to application of this structure to GaN-based semiconductor laser diodes which require increase in power.

### First Conventional Example

Referring to FIGS. 29A to 29D, a semiconductor laser diode of a first conventional example described in Published Japanese Patent Application No. 2008-34587 will be described.

The GaN-based semiconductor laser diode of the first conventional example includes a ridge-waveguide structure (a ridge stripe) 101a formed by dry-etching a GaN-based semiconductor layer 101 using a P-side electrode 104 formed of a laminate of a Pd (palladium) film 102 and a Pt (platinum) film 103 as an etch mask. No-current injection regions 101b are formed at the ends of a cavity by removing the P-side electrode 104 made of the Pd/Pt laminate.

The ridge stripe 101a formed in an upper cladding layer in the GaN-based semiconductor layer 101 as shown in FIGS. 29A to 29D confines a current injected into an active layer (not shown) to limit the width of a resonance region for laser oscillation in the active layer. This allows the stabilization of a lateral mode of laser light, and the reduction in operating current. Further, with the presence of the no-current injection regions 101b at the ends of the cavity, COD at end faces of the cavity is efficiently prevented, and the cavity life can be increased.

Specifically, the GaN-based semiconductor laser diode of the first conventional example is fabricated in the following processes.

First, as shown in FIG. 29A, a Pd film 102 and a Pt film 103 are stacked in this order to form a P-side electrode 104 on a GaN-based semiconductor layer 101 epitaxially grown on an N-type GaN substrate 100.

Then, as shown in FIG. 29B, the GaN-based semiconductor layer 101 is dry-etched using the P-side electrode 104 as an etch mask to form a ridge stripe 101a. The etching is performed so that the Pt film 103, which is the upper one of the metal films forming the P-side electrode 104, is almost removed at the end of the etching.

Then, as shown in FIG. 29C, the Pd film 102 and the remaining Pt film 103 are etched away using aqua regia except for parts thereof serving as the P-side electrode 104. Thus, no-current injection regions 101b are provided on the ridge stripe 101a.

Then, as shown in FIG. 29D, a dielectric film 105 is formed on the GaN-based semiconductor layer 101 including the ridge stripe 101a. Then, a resist pattern having a predetermined opening above the ridge stripe is formed on the dielectric film 105, and part of the dielectric film 105 above the ridge stripe 101a is removed by, for example, reactive ion etching (RIE), to expose the Pt film 103 from the dielectric film 105. After that, a pad electrode 106 formed of a metal laminate film of Ti (titanium)/Pt (platinum)/Au (gold) is formed by a lift-off process.

### Second Conventional Example

A second conventional example manufactured in a different manner from the first conventional example is described in Published Japanese Patent Application No. 2006-59881. This will be described with reference to FIGS. 30A to 30C.

First, as shown in FIG. 30A, a resist film 109 is formed to cover a ridge stripe 101a on which a dielectric film 105 has been formed. Then, the resist film 109 is etched back by ashing to expose a top surface of the dielectric film 105 above the ridge stripe 101a.

Then, as shown in FIG. 30B, the dielectric film 105 is wet-etched using the resist film 109 as a mask, so that a contact layer 108 consisting an upper portion of the ridge stripe 101a is exposed from the dielectric film 105 as shown in FIG. 30C. Then, though not shown, a metal film for forming an electrode is deposited on the resist film 109 and the exposed contact layer 108, and the metal film deposited on the resist film 109 is removed together with the resist film 109 by a so-called lift-off process to form an electrode on the contact layer 108. The contact layer 108 and the electrode thus formed are thicker than part of the dielectric film 105 parallel to the substrate surface. Therefore, when the resist film 109 is etched back, and then the dielectric film 105 is selectively etched using the resist film 109 as a mask, the side surfaces of the ridge stripe 101a except for the contact layer 108 can be prevented from exposure, i.e., the side surfaces of the ridge stripe 101a except for the contact layer 108 can remain covered with the dielectric film 105.

In the second conventional example, a major difference from the first conventional example is that the electrode is formed after the forming of the ridge stripe 101a and the etching of the dielectric film 105. This can suppress contamination by constituents of the electrode (remaining substances) and degradation of the Pd film 102. Further, since the etch-back process is used in the second conventional example, the electrode can be formed to cover not only the top surface of the contact layer 108, but also the side surfaces of the contact layer 108. This is advantageous to reduce contact resistance.

### SUMMARY

In the first conventional example, the GaN-based semiconductor layer is dry-etched using the P-side electrode made of the Pd/Pt laminate (a conductive film) as an etch mask to form the ridge stripe. Further, part of the P-side electrode for forming the no-current injection regions is removed using aqua regia.

According to the first conventional example, however, it is difficult to completely remove the metal films from the no-current injection regions on the top surface of the contact layer. If the metal film remains on the no-current injection regions on the top surface of the contact layer, reactive current which does not contribute to laser oscillation may be increased at an interface between the GaN-based semiconductor layer and the dielectric film, and adhesion at the interface between the dielectric film and the contact layer may be impaired in the no-current injection regions. This may result in peeling of the dielectric film and failure in heat dissipation.

When the GaN-based semiconductor layer is etched using the P-side electrode as a mask, contamination by metal elements forming the electrode may occur in a diffusion process performed later. Since the Pd film is particularly likely to absorb hydrogen, the P-side electrode may deteriorate due to the effect of atmospheric gas in the diffusion process, and therefore, device resistance may be increased.

Further, the provision of the no-current injection regions near the end faces of the cavity does not effectively suppress the COD when the area of the no-current injection regions is too small. However, when the area of the no-current injection regions is too large, they become a saturable absorber. As a result, discontinuous hops may appear in a current-optical output characteristic. For this reason, on the top surface of the ridge stripe, it is necessary that an end of the dielectric film forming the no-current injection region and an end of the P-side electrode are arranged with accuracy so as not to separate from each other.

In the method according to the first conventional example, wet etching needs to be performed. When the aqua regia is used as an etchant, the rate of etching the Pt film is very low as compared with the rate of etching the Pd film, even when a small thickness of the Pt film is supposed to leave. This method is not suitable for controlling the length of the no-current injection region with high accuracy and stability to, for example, about 10 μm or smaller.

Further, when the resist film is etched back as performed in the second conventional example, it is impossible to leave the dielectric film so as to form the no-current injection region. The process of selectively forming the dielectric film on the entirely exposed top surface of the ridge stripe is complicated, and therefore, a good no-current injection region cannot be formed.

A lift-off process, for example, may be a possible process for forming the Pd/Pt film selectively and stably as the P-side electrode on the ridge stripe. However, after etching the dielectric film only by the method according to the second conventional example, it is difficult to deposit the Pd/Pt film and remove it by the lift-off process.

To solve the problems described above, the present disclosure allows the reduction of the contact resistance of an electrode formed on a ridge stripe having a no-current injection region, the suppression of discontinuous hops that appear in the current-optical output characteristic, and the implementation of high-power operation.

For the above-described purposes, the present disclosure proposes a method for manufacturing a semiconductor light emitting device including: etching back a first resist film; inactivating the first resist film; and forming a second resist film on the inactivated first resist film as a mask for a no-current injection region made of a dielectric film, so as to form a no-current injection region made of a dielectric film on a ridge stripe.

Specifically, the disclosed semiconductor light emitting device includes: a semiconductor laminate which includes at least a first cladding layer of a first conductivity type, an active layer, a second cladding layer of a second conductivity type, and a contact layer of the second conductivity type stacked in this order on a semiconductor substrate, the semiconductor laminate having a ridge portion including the second cladding layer and the contact layer shaped into a stripe; a dielectric film which is formed on the second cladding layer to cover the ridge portion and has an opening selectively exposing a top of the ridge portion; and a first electrode which is formed on the top of the ridge portion and is in contact with a top surface and a side surface of the contact layer exposed from the dielectric film, wherein the dielectric film includes a no-current injection region which covers at least one of ends of the ridge portion near end faces of a cavity so as to block current injection into the active layer, and the no-current injection region of the dielectric film is in contact with the contact layer.

According to the disclosed semiconductor light emitting device, the first electrode is formed also on the side surface of the contact layer. This increases a contact area between the first electrode and the contact layer. Moreover, since the first electrode becomes less likely to peel from the contact layer, contact resistance can be reduced. This allows the semiconductor light emitting device to achieve oscillation at low current and high power operation. Further, since the dielectric film and the contact layer are brought into contact with each other with high adhesion, current leak via the no-current injection region is less likely to occur. At the same time, since the dielectric film is less likely to peel, high heat dissipation is achieved. Further, since the first electrode is almost in contact with the no-current injection region, the heat dissipation is further improved. Thus, a high-power semiconductor light emitting device can be provided with good linearity in a current-optical output (IL) characteristic and a long life characteristic.

In the disclosed semiconductor light emitting device, it is preferable that the first electrode is in contact with the entire top surface and both side surfaces of the contact layer exposed from the dielectric film.

This structure maximizes the contact area between the first electrode and the contact layer, and therefore, the first electrode does not peel. Thus, the contact resistance can be minimized.

In the disclosed semiconductor light emitting device, a width of the ridge portion may vary in a direction of extension of the ridge portion.

This structure increases the contact area between the first electrode and the contact layer to a further extent, and therefore, the first electrode does not peel. Thus, the contact resistance of the first electrode can be reduced to a further extent.

In the semiconductor light emitting device, the semiconductor substrate and the semiconductor laminate may be made of a group III-V nitride compound semiconductor represented by InₓAl_{y}Ga_{1-x-y}N (wherein 0≦x≦1, 0≦y≦1, x+y≦1).

With use of such semiconductor material, an oscillation wavelength can be set within a range of bluish purple to green.

In this case, the first electrode may contain nickel (Ni) or palladium (Pd) in part thereof in contact with the contact layer.

This structure allows the reduction in contact resistance of the first electrode to the contact layer made of the group III-V nitride compound semiconductor.

The disclosed semiconductor light emitting device may further include: a second electrode formed on the dielectric film and the first electrode, wherein the second electrode is formed so that an end of the second electrode near the end face of the cavity is positioned above the no-current injection region.

This structure allows the prevention of decrease in level of COD caused by electric field concentration.

In the disclosed semiconductor light emitting device, a width of the end of the second electrode near the end face of the cavity may be larger than the width of the ridge portion.

The first electrode, which is formed on the top surface of the ridge portion, is likely to cause electric field concentration. When the second electrode is used as a pad electrode, the electric field concentration in the first electrode can be suppressed by setting the width of the second electrode larger than the width of the ridge portion. This allows high power operation.

In the semiconductor light emitting device, side surfaces of the ridge portion may be inclined so that the ridge portion has a trapezoidal cross section with its width increasing in a direction from the top to the bottom of the ridge portion.

This structure allows the smooth formation of the second electrode (e.g., a pad electrode) on the dielectric film. Therefore, the second electrode can be prevented from break at the corner of the ridge portion.

In the disclosed semiconductor light emitting device, the dielectric film may be formed so that a distance between outer surfaces of parts of the dielectric film covering the side surfaces of the ridge portion increases in a direction from the top to the bottom of the ridge portion.

This structure also allows the smooth formation of the second electrode (e.g., a pad electrode) on the dielectric film. Therefore, the second electrode can be prevented from break at the corner of the ridge portion.

In the disclosed semiconductor light emitting device, a distance between an end of the first electrode near the end face of the cavity and the end face of the cavity may be 3 μm to 10 μm, both inclusive.

This structure allows the suppression of discontinuous hops that appear in the current-optical output characteristic, and the suppression of increase in operating current in response to increase in threshold current value. Therefore, high power operation can be implemented. In particular, when the semiconductor light emitting device is used in an optical disc system, and when the discontinuous hops appear in the current-optical output characteristic near the threshold current, monitoring and control of the optical output cannot be performed with stability. The disclosed device can suppress the hops.

A disclosed method for manufacturing the semiconductor light emitting device includes: stacking at least an n-type cladding layer, an active layer, a p-type cladding layer and a p-type contact layer, which are semiconductor layers, in this order on a semiconductor substrate to form a semiconductor laminate; etching the p-type cladding layer and the p-type contact layer to form a ridge portion in the shape of a stripe; forming a dielectric film on the semiconductor laminate to cover the ridge portion; forming a first resist film on the dielectric film, and etching back the first resist film to expose part of the dielectric film above the ridge portion from the first resist film; inactivating the first resist film; forming a second resist film on the first resist film including the part of the dielectric film above the ridge portion; performing light exposure and development on the second resist film to form an opening in the second resist film which exposes the part of the dielectric film above the ridge portion, while at least one of ends of the dielectric film near the end faces of the cavity remains covered; etching the dielectric film using the first resist film and the second resist film as a mask to selectively expose a top of the ridge portion from the dielectric film; forming a first conductive film on the first resist film and the second resist film including the exposed top of the ridge portion; removing the first resist film and the second resist film to selectively form a first electrode made of the first conductive film on the ridge portion; and forming a second conductive film on the first electrode, and patterning the second conductive film to form a second electrode made of the second conductive film.

According to the disclosed method for manufacturing the semiconductor light emitting device, a two-resist process is employed, i.e., the first resist film is etched back, and the second resist film having a predetermined opening is formed on the etched back first resist film. This can ensure symmetry of the dielectric film and that of the first conductive film formed on the ridge portion. Moreover, since the no-current injection region in which the first conductive film is not formed is provided on part of the ridge portion at the end of the cavity, misalignment of a center of an optical axis can be avoided. This implements a high level of COD. Further, since the first electrode is not formed on the dielectric film, the first electrode is less likely to peel.

In the disclosed method for manufacturing the semiconductor light emitting device, in the forming the ridge portion, the ridge portion may be formed so that its width increases in a direction from the top to the bottom of the ridge portion.

In the disclosed method for manufacturing the semiconductor light emitting device, in the forming of the dielectric film, the dielectric film may be formed so that a distance between outer surfaces of parts of the dielectric film covering the side surfaces of the ridge portion increases in a direction from the top to the bottom of the ridge portion.

In the disclosed method for manufacturing the semiconductor light emitting device, the increasing the distance between the outer surfaces of the parts of the dielectric film covering the side surfaces of the ridge portions in the direction from the top to the bottom of the ridge portion may be implemented by dry etching using inert gas.

In this case, the inert gas may be argon.

The disclosed method for manufacturing the semiconductor light emitting device may further include: exposing the dielectric film to an agent which improves adhesion between the dielectric film and the second resist film between the inactivating the first resist film and the forming the second resist film.

In the disclosed method for manufacturing the semiconductor light emitting device, the exposing the ridge portion from the dielectric film may be implemented by wet etching.

In the disclosed method for manufacturing the semiconductor light emitting device, the inactivating the first resist film may be implemented by UV irradiation or baking at a temperature of 150° C. or higher.

In the disclosed method for manufacturing the semiconductor light emitting device, the semiconductor substrate and the semiconductor laminate may be made of a group III-V nitride compound semiconductor represented by InₓAl_{y}Ga_{1-x-y}N (wherein 0≦x≦1, 0≦y≦1, x+y≦1).

As described above, according to the disclosed semiconductor light emitting device and the method for manufacturing the same, the contact resistance of the electrode formed on the ridge stripe including the no-current injection region can be reduced, and the discontinuous hops that appear in the current-optical output characteristic can be suppressed. Therefore, high power operation can be implemented.

### BRIEF DESCRIPTION OF THE DRAWINGS

FIG. 1 is a plan view illustrating a semiconductor light emitting device of a first example embodiment.

FIGS. 2A and 2B show the semiconductor light emitting device of the first example embodiment, FIG. 2A is a cross-sectional view taken along the line A-A shown in FIG. 1, and FIG. 2B is a cross-sectional view taken along the line B-B shown in FIG. 1.

FIGS. 3A and 3B show a process of a method for manufacturing the semiconductor light emitting device of the first example embodiment, FIG. 3A is a cross-sectional view corresponding to the line A-A shown in FIG. 1, and FIG. 3B is a cross-sectional view corresponding to the line B-B shown in FIG. 1.

FIGS. 4A and 4B show a process of the method for manufacturing the semiconductor light emitting device of the first example embodiment, FIG. 4A is a cross-sectional view corresponding to the line A-A shown in FIG. 1, and FIG. 4B is a cross-sectional view corresponding to the line B-B shown in FIG. 1.

FIGS. 5A and 5B show a process of the method for manufacturing the semiconductor light emitting device of the first example embodiment, FIG. 5A is a cross-sectional view corresponding to the line A-A shown in FIG. 1, and FIG. 5B is a cross-sectional view corresponding to the line B-B shown in FIG. 1.

FIGS. 6A and 6B show a process of the method for manufacturing the semiconductor light emitting device of the first example embodiment, FIG. 6A is a cross-sectional view corresponding to the line A-A shown in FIG. 1, and FIG. 6B is a cross-sectional view corresponding to the line B-B shown in FIG. 1.

FIGS. 7A and 7B show a process of the method for manufacturing the semiconductor light emitting device of the first example embodiment, FIG. 7A is a cross-sectional view corresponding to the line A-A shown in FIG. 1, and FIG. 7B is a cross-sectional view corresponding to the line B-B shown in FIG. 1.

FIGS. 8A and 8B show a process of the method for manufacturing the semiconductor light emitting device of the first example embodiment, FIG. 8A is a cross-sectional view corresponding to the line A-A shown in FIG. 1, and FIG. 8B is a cross-sectional view corresponding to the line B-B shown in FIG. 1.

FIGS. 9A and 9B show a process of the method for manufacturing the semiconductor light emitting device of the first example embodiment, FIG. 9A is a cross-sectional view corresponding to the line A-A shown in FIG. 1, and FIG. 9B is a cross-sectional view corresponding to the line B-B shown in FIG. 1.

FIGS. 10A and 10B show a process of the method for manufacturing the semiconductor light emitting device of the first example embodiment, FIG. 10A is a cross-sectional view corresponding to the line A-A shown in FIG. 1, and FIG. 10B is a cross-sectional view corresponding to the line B-B shown in FIG. 1.

FIGS. 11A and 11B show a process of a method for manufacturing a modified example of the semiconductor light emitting device of the first example embodiment, FIG. 11A is a cross-sectional view corresponding to the line A-A shown in FIG. 1, and FIG. 11B is a cross-sectional view corresponding to the line B-B shown in FIG. 1.

FIGS. 12A and 12B show a process of the method for manufacturing the modified example of the semiconductor light emitting device of the first example embodiment, FIG. 12A is a cross-sectional view corresponding to the line A-A shown in FIG. 1, and FIG. 12B is a cross-sectional view corresponding to the line B-B shown in FIG. 1.

FIGS. 13A and 13B show a process of the method for manufacturing the modified example of the semiconductor light emitting device of the first example embodiment, FIG. 13A is a cross-sectional view corresponding to the line A-A shown in FIG. 1, and FIG. 13B is a cross-sectional view corresponding to the line B-B shown in FIG. 1.

FIGS. 14A and 14B show a process of the method for manufacturing the modified example of the semiconductor light emitting device of the first example embodiment, FIG. 14A is a cross-sectional view corresponding to the line A-A shown in FIG. 1, and FIG. 14B is a cross-sectional view corresponding to the line B-B shown in FIG. 1.

FIG. 15 is a plan view illustrating the modified example of the semiconductor light emitting device of the first example embodiment.

FIGS. 16A and 16B show a process of the method for manufacturing the semiconductor light emitting device of the first example embodiment, FIG. 16A is a cross-sectional view corresponding to the line A-A shown in FIG. 1, and FIG. 16B is a cross-sectional view corresponding to the line B-B shown in FIG. 1.

FIGS. 17A and 17B show a process of the method for manufacturing the semiconductor light emitting device of the first example embodiment, FIG. 17A is a cross-sectional view corresponding to the line A-A shown in FIG. 1, and FIG. 17B is a cross-sectional view corresponding to the line B-B shown in FIG. 1.

FIGS. 18A and 18B show a process of the method for manufacturing the semiconductor light emitting device of the first example embodiment, FIG. 18A is a cross-sectional view corresponding to the line A-A shown in FIG. 1, and FIG. 18B is a cross-sectional view corresponding to the line B-B shown in FIG. 1.

FIG. 19 is a partial plan view illustrating an enlargement of a no-current injection region in the semiconductor light emitting device of the first example embodiment.

FIGS. 20A to 20D show a relationship between optical output and efficiency with respect to injection current in the semiconductor light emitting device of the first example embodiment, FIG. 20A is a graph corresponding to the device in which the no-current injection region is not provided, FIG. 20B is a graph corresponding to the device in which the no-current injection region is 3 μm in length, FIG. 20C is a graph corresponding to the device in which the no-current injection region is 5 μm in length, and FIG. 20D is a graph corresponding to the device in which the no-current injection region is 10 μm in length.

FIG. 21 is a partial plan view illustrating an enlargement of the no-current injection region in the semiconductor light emitting device of the first example embodiment, in which a position of an end of a pad electrode is varied.

FIGS. 22A to 22C show a relationship between optical output and injection current in the semiconductor light emitting device of the first example embodiment, FIG. 22A is a graph corresponding to the device in which the no-current injection region is not provided and a P-side electrode is exposed from a pad electrode, FIG. 22B is a graph corresponding to the device in which the no-current injection region is 5 μm in length and the P-side electrode is exposed from the pad electrode, and FIG. 22C is a graph corresponding to the device in which the no-current injection region is 5 μm in length and the P-side electrode is not exposed from the pad electrode.

FIG. 23 is a plan view illustrating a semiconductor light emitting device of a second example embodiment.

FIGS. 24A and 24B show the semiconductor light emitting device of the second example embodiment, FIG. 24A is a cross-sectional view taken along the line A-A shown in FIG. 23, and FIG. 24B is a cross-sectional view taken along the line B-B shown in FIG. 23.

FIGS. 25A and 25B show a process of a method for manufacturing the semiconductor light emitting device of the second example embodiment, FIG. 25A is a cross-sectional view corresponding to the line A-A shown in FIG. 23, and FIG. 25B is a cross-sectional view corresponding to the line B-B shown in FIG. 23.

FIGS. 26A and 26B show a process of the method for manufacturing the semiconductor light emitting device of the second example embodiment, FIG. 26A is a cross-sectional view corresponding to the line A-A shown in FIG. 23, and FIG. 26B is a cross-sectional view corresponding to the line B-B shown in FIG. 23.

FIGS. 27A and 27B show a process of the method for manufacturing the semiconductor light emitting device of the second example embodiment, FIG. 27A is a cross-sectional view corresponding to the line A-A shown in FIG. 23, and FIG. 27B is a cross-sectional view corresponding to the line B-B shown in FIG. 23.

FIGS. 28A and 28B show a process of the method for manufacturing the semiconductor light emitting device of the second example embodiment, FIG. 28A is a cross-sectional view corresponding to the line A-A shown in FIG. 23, and FIG. 28B is a cross-sectional view corresponding to the line B-B shown in FIG. 23.

FIGS. 29A to 29D show a major part of a method for manufacturing a semiconductor laser diode of a first conventional example, FIG. 29A is a perspective view illustrating a process for forming a metal mask, FIG. 29B is a perspective view illustrating a process for forming a ridge stripe, FIG. 29C is a perspective view illustrating a process for forming no-current injection regions, and FIG. 29D is a perspective view illustrating a process for forming a pad electrode.

FIGS. 30A to 30C show a major part of a method for manufacturing a semiconductor laser diode of a second conventional example, FIG. 30A is a cross-sectional view illustrating a process of ashing a resist pattern, FIG. 30B is a cross-sectional view illustrating a process of etching a dielectric film, and FIG. 30C is a cross-sectional view illustrating a process of forming a contact layer.

### DETAILED DESCRIPTION

Embodiments of the disclosed semiconductor light emitting device (a GaN-based semiconductor laser diode) and a method for manufacturing the same will be described below with reference to the drawings. The disclosed semiconductor light emitting device is basically configured as described above. However, it may be modified in various ways, and is not limited to the following embodiments.

### First Example Embodiment

A first example embodiment will be described with reference to the drawings.

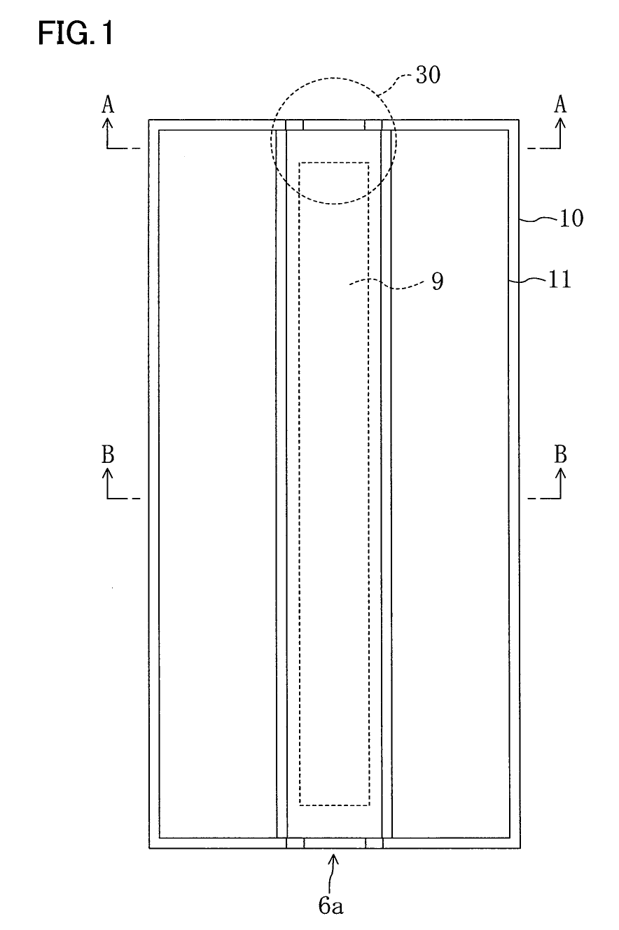

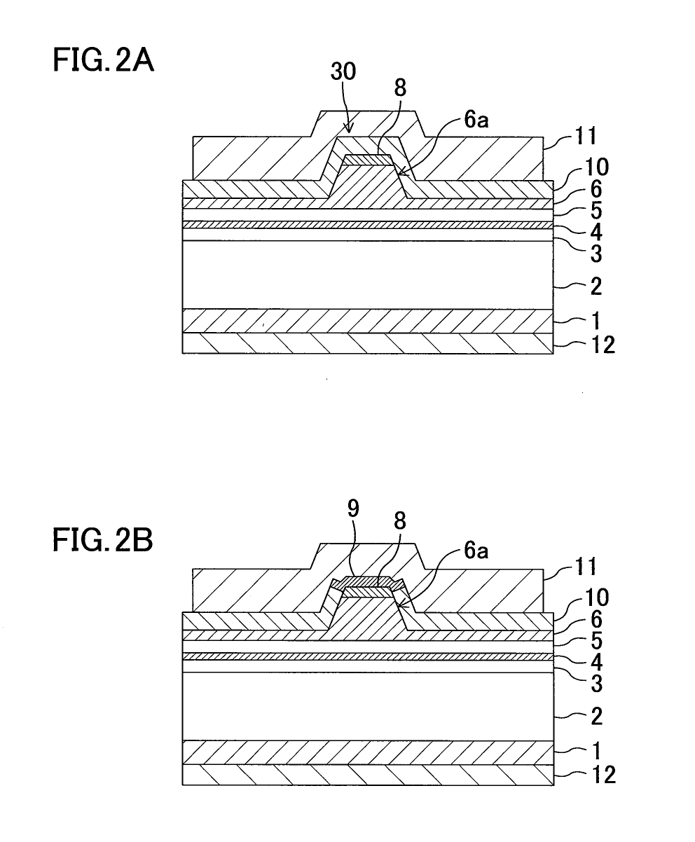

FIG. 1 shows a planar structure of a GaN-based semiconductor laser diode according to the first example embodiment. FIG. 2A shows a cross-sectional structure of the same corresponding to the line A-A shown in FIG. 1, and FIG. 2B shows a cross-sectional structure of the same corresponding to the line B-B shown in FIG. 1.

As shown in FIGS. 2A and 2B, an about 2.5 μm thick n-type cladding layer 2 made of n-type AlₓGa₁₋ₓN (x=0.03) is formed on a substrate 1 made of, for example, n-type GaN. An about 0.1 μm thick n-type optical guide layer 3 made of n-type GaN is formed on the n-type cladding layer 2. Further, a multiple quantum well active layer 4 including an about 3 nm thick well layer made of InₓGa_{1-z}N (z=0.07) and an about 8 nm thick barrier layer made of InₛGa₁₋ₛN (s=0.01) is formed on the n-type optical guide layer 3. On the multiple quantum well active layer 4, an about 0.1 μm thick p-type optical guide layer 5 made of p-type GaN is formed.

A p-type cladding layer 6 made of p-type AlₜGa₁₋ₜN (t=0.03) is formed on the p-type optical guide layer 5. The p-type cladding layer 6 is provided with an about 0.5 μm thick ridge portion 6a, which is in the shape of a stripe when viewed in plan and is in the shape of a tapered mesa when viewed in cross-section. The tapered mesa shape mentioned herein is a trapezoidal cross section with a width of the ridge portion 6a decreasing toward the top of the substrate 1. An about 60 nm thick contact layer 8 made of p-type GaN is formed on the ridge portion 6a.

As shown in FIGS. 1 and 2B, palladium (Pd) and platinum (Pt) are stacked on the contact layer 8 to form a P-side electrode 9 which is in ohmic contact with the contact layer 8. A dielectric film 10 made of, for example, silicon oxide (SiO₂), is formed on both side surfaces of the ridge portion 6a and on the p-type cladding layer 6 on both sides of the ridge portion 6a. The dielectric film 10 has an opening in a region where the P-side electrode 9 is formed. Further, as shown in FIGS. 1 and 2A, a no-current injection region 30 is covered with the dielectric film 10. Specifically, the P-side electrode 9, which covers the top surface and the side surfaces of the contact layer 8 exposed from the dielectric film 10, is not formed on the side surfaces of the ridge portion 6a of the p-type cladding layer 6, and is not formed on the dielectric film 10 except for the ridge portion 6a. The P-side electrode 9 and the remaining of the P-side electrode 9 after etching do not present between the dielectric film 10 which functions as the no-current injection region 30 and the contact layer 8 near an end face of a cavity. In the first example embodiment, the no-current injection regions 30 are formed at a front end face and a rear end face of the cavity. However, the no-current injection region may be formed at any one of the front and rear end faces of the cavity, preferably at the front end face of the cavity.

As shown in FIG. 1 and FIGS. 2A and 2B, a pad electrode 11 made of a laminate of titanium (Ti)/platinum (Pt)/gold (Au) stacked in this order is formed on the dielectric film 10 and the P-side electrode 9. An N-side electrode 12 which is in ohmic contact with the substrate 1 is formed on the surface (the rear surface) of the substrate 1 opposite the n-type cladding layer 2.

In the GaN-based semiconductor laser diode of the first example embodiment, a contact area between the P-side electrode 9 and the contact layer 8 is increased, and therefore, device resistance can be reduced. Further, since the no-current injection regions 30 made of the dielectric film 10 are provided at both ends of the ridge portion 6a, the P-side electrode 9 is less likely to peel near the end faces of the cavity. This can reduce variations in device resistance.

The no-current injection region 30 made of the dielectric film 10 is brought into contact with the contact layer 8 with good adhesion. This can suppress current leakage via the no-current injection region 30, and therefore, the dielectric film 10 is less likely to peel.

Further, since the P-side electrode 9 is almost in contact with the no-current injection region 30, excellent heat dissipation is achieved near the end face of the cavity. Moreover, since the no-current injection region 30 can be formed with high accuracy, discontinuous hops that appear in a current-optical output characteristic during high power operation can be suppressed. Thus, a GaN-based semiconductor laser diode having good linearity in the current-optical output characteristic and a long life characteristic can be obtained.

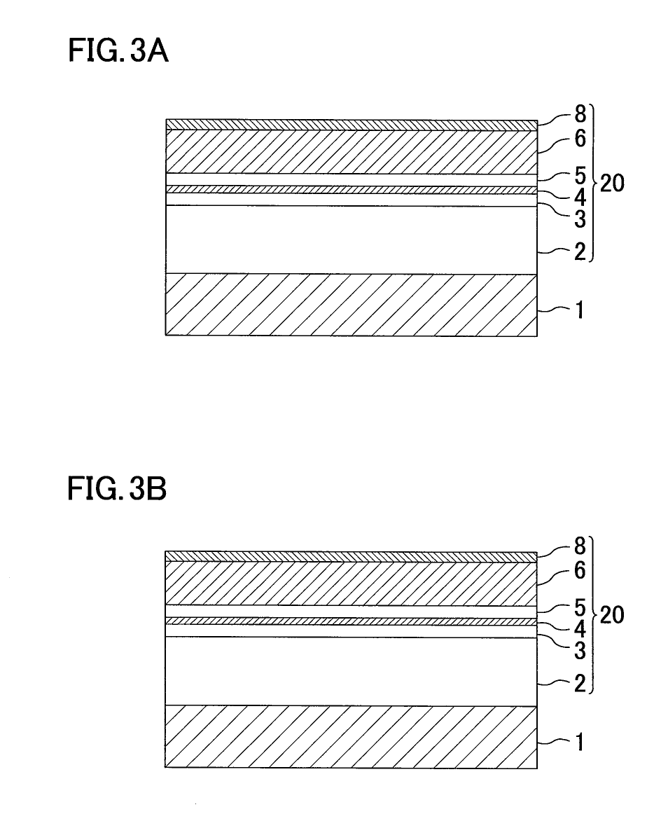

Hereinafter, a method for manufacturing the GaN-based semiconductor laser diode according to the first example embodiment will be described with reference to FIGS. 3A and 3B to FIGS. 18A and 18B. Each figure accompanied with A shows a cross-sectional structure corresponding to the line A-A shown in FIG. 1, and each figure accompanied with B shows a cross-sectional structure corresponding to the line B-B shown in FIG. 1.

First, as shown in FIGS. 3A and 3B, a semiconductor laminate 20 is formed on a substrate 1 made of n-type GaN. Specifically, an n-type cladding layer 2, an n-type optical guide layer 3, a multiple quantum well active layer 4, a p-type optical guide layer 5, an about 0.5 μm thick p-type cladding layer 6, and a contact layer 8 are epitaxially grown in a sequential manner on a principle surface of the substrate 1 by, for example, metal-organic chemical vapor deposition (MOCVD).

As materials for the epitaxially growth of the semiconductor laminate 20, for example, trimethyl gallium (TMG) may be used as gallium (Ga), trimethyl aluminum may be used as aluminum (Al), trimethyl indium may be used as indium (In), and ammonia (NH₃) may be used as nitrogen (N). Cyclopentadienyl magnesium (Cp₂Mg) may be used as magnesium (Mg) as a p-type dopant, and silane (SiH₄) may be used as silicon (Si) as an n-type dopant. Further, nitrogen (N₂) and hydrogen (H₂) can be used as carrier gas for material gas.

The present disclosure is not limited to the semiconductor laminate 20 and the manufacturing method described above. The present disclosure can be applied even when the method for growing the semiconductor laminate 20 is changed, or the compositions of the semiconductor layers forming the semiconductor laminate 20 are changed.

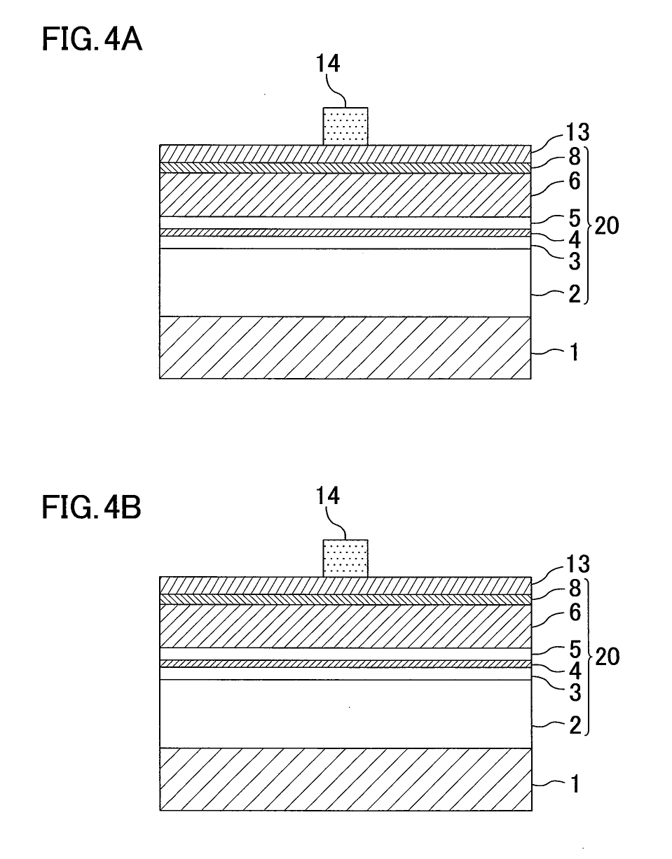

Then, as shown in FIGS. 4A and 4B, a mask layer 13 having a desired thickness and made of silicon oxide (SiO₂) is formed on the contact layer 8 consisting the semiconductor laminate 20. Then, a resist pattern 14 in the shape of a stripe extending in a predetermined direction is formed on the mask layer 13 by lithography.

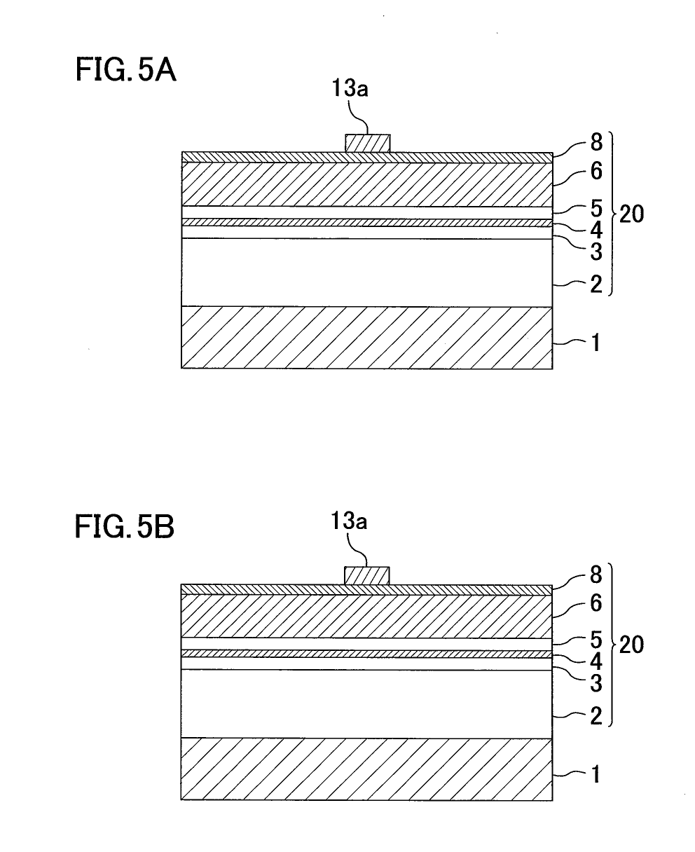

Then, as shown in FIGS. 5A and 5B, using the stripe-shaped resist pattern 14 as a mask, the mask layer 13 is etched into a mask pattern 13a in the shape of a stripe having a predetermined width by, for example, dry etching such as reactive ion etching (RIE), or wet etching using buffered hydrogen fluoride (BHF) or the like. The mask pattern 13a is generally formed by dry etching which is advantageous in controllability of etching. After that, the resist pattern 14 is removed.

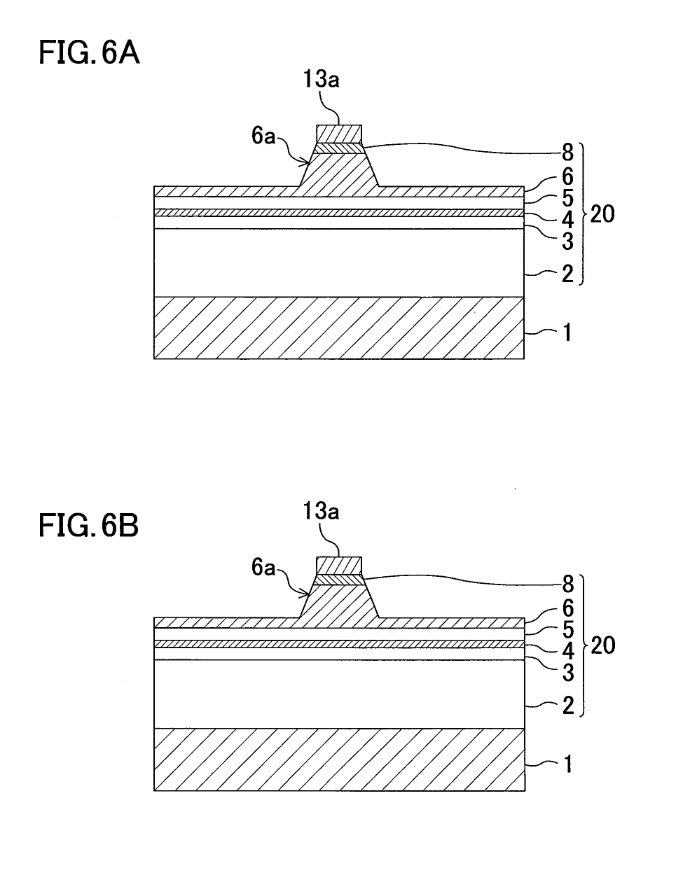

Then, as shown in FIGS. 6A and 6B, using the mask pattern 13a as a mask, the contact layer 8 and the cladding layer 6 are sequentially etched to form a ridge portion 6a including the contact layer 8 and an upper portion of the cladding layer 6 by inductively coupled plasma (ICP) etching using a gas mixture prepared by adding silicon tetrachloride (SiCl₄) gas, which is sedimentary gas, to chlorine (Cl₂) gas.

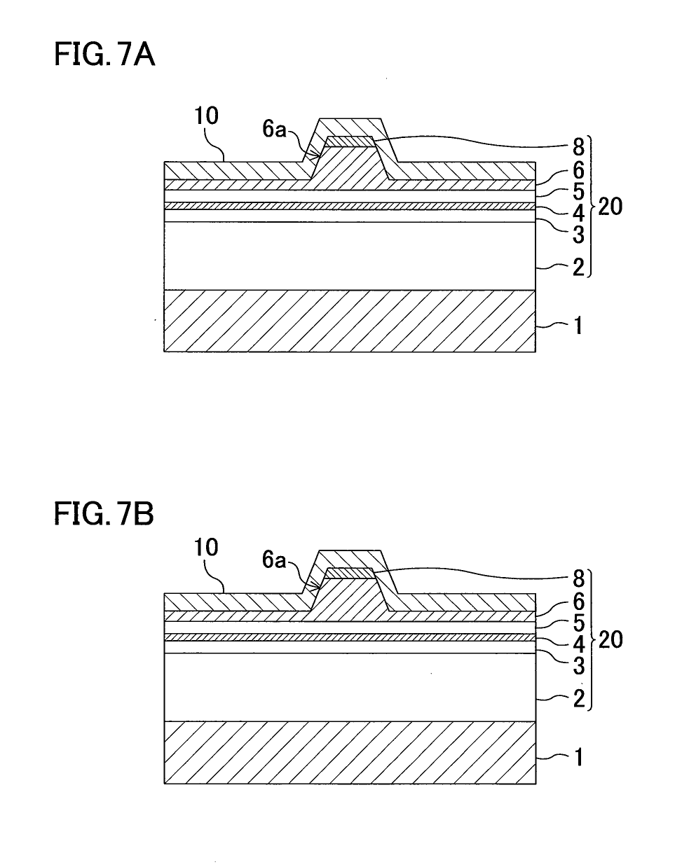

Then, as shown in FIGS. 7A and 7B, the mask pattern 13a is removed by wet etching using buffered hydrogen fluoride (BHF) or the like. In this manner, a process of forming the ridge portion 6a, which is in the shape of a tapered mesa having the side surfaces inclined at an angle of about 5° to 30° from a normal to the principle surface of the substrate 1, is completed. The angle of inclination of the side surfaces of the ridge portion 6a can be changed by changing the ratio of the sedimentary SiCl₄ gas added. Then, a dielectric film 10 made of SiO₂ is formed by chemical vapor deposition (CVD) to cover the entire surface of the p-type cladding layer 6 including the ridge portion 6a. A suitable thickness of the dielectric film 10 may be about 50 nm to 1000 nm. A preferable thickness thereof may be about 50 nm to 300 nm in view of optical confinement by the dielectric film 10 and the effect of stress of the dielectric film 10 on the semiconductor laminate 20.

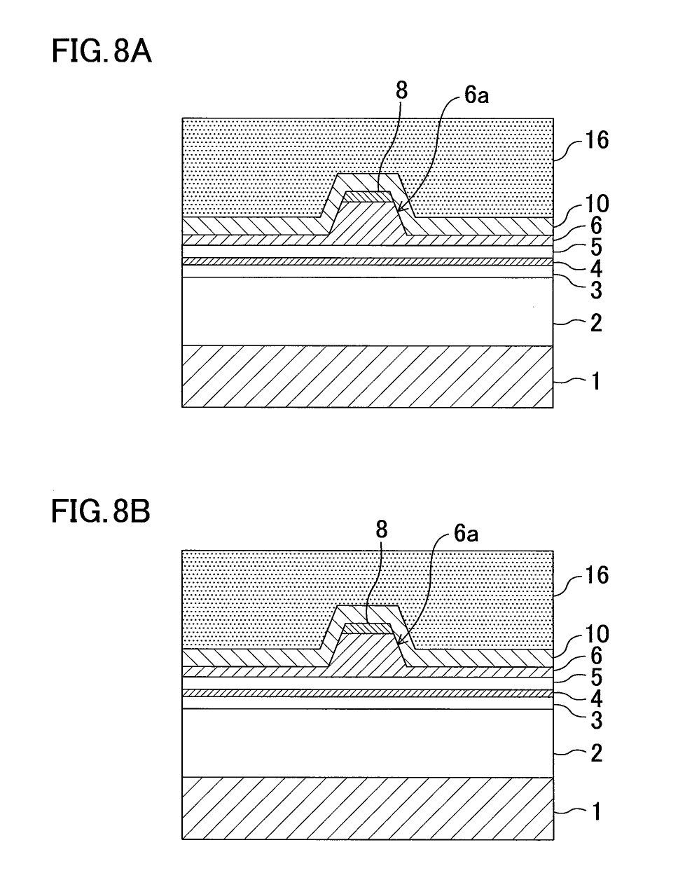

Then, as shown in FIGS. 8A and 8B, a first resist film 16 whose thickness is 1.5 or more times as large as the height of the ridge portion 6a is formed on the entire surface of the dielectric film 10. With such thickness, the first resist film 16 can be provided with good flatness, and a top surface thereof becomes less likely to be influenced by the ridge portion 6a. Then, the first resist film 16 thus formed is heated at a temperature of 150° C. or higher, e.g., about 170° C., for about 20 minutes to inactivate the first resist film 16. The heating for inactivation of the first resist film 16 can be replaced with UV curing by UV irradiation.

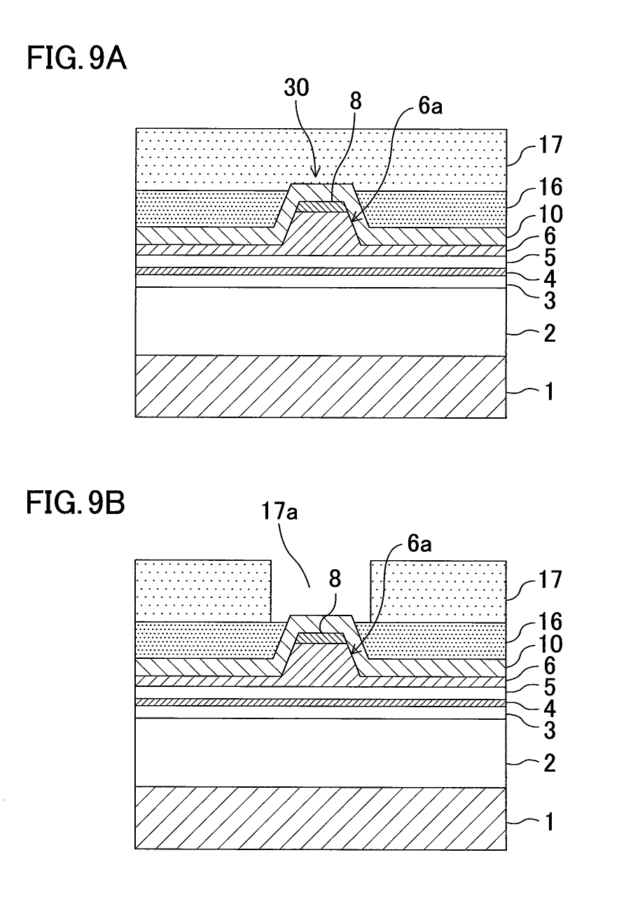

Then, as shown in FIGS. 9A and 9B, the first resist film 16 is treated with oxygen plasma to etch back the first resist film 16 by a desired thickness, so that part of the dielectric film 10 above the top of the ridge portion 6a is exposed. This etch back process can be implemented by etching back the first resist film 16 in a controlled manner using an ashing apparatus which treats wafers one by one with high uniformity, and by measuring the thickness of the first resist film 16 on the dielectric film 10 with high accuracy using an optical film thickness measurement technique, such as reflectance spectroscopy. Subsequently, a second resist film 17 for patterning the P-side electrode is applied onto the entire surface of the etched-back first resist film 16 and the exposed dielectric film 10. In this process, when the dielectric film 10 remains on parts of the ridge portion 6a as the no-current injection regions 30 at the end faces of the cavity as shown in FIG. 1, the dielectric film 10 exposed from the first resist film 16 is exposed to hexamethyldisilazane (HMDS) as a pretreatment for ensuring adhesion between the second resist film 17 and the dielectric film 10.

Then, the pretreated second resist film 17 is patterned by lithography to form an opening 17a having a width larger than the width of the contact layer 8 in part of the second resist film 17 above the ridge portion 6a. In this process, the second resist film 17 is patterned into a mask in which the opening does not expose the ends of the ridge portion 6a as shown in FIG. 9A. This allows the provision of the no-current injection regions 30 at the ends of the ridge portion 6a where the P-side electrode is not formed. The dimension of the no-current injection region 30 may be about 3 μm to 10 μm, both inclusive, more preferably, about 5 μm, from the end face of the cavity. Since the opening 17a which is wider than the width of the top surface of the ridge portion 6a in the second resist film 17 is provided, a self-alignment process can be performed, which does not depend on alignment accuracy of a pattern in the lithography process.

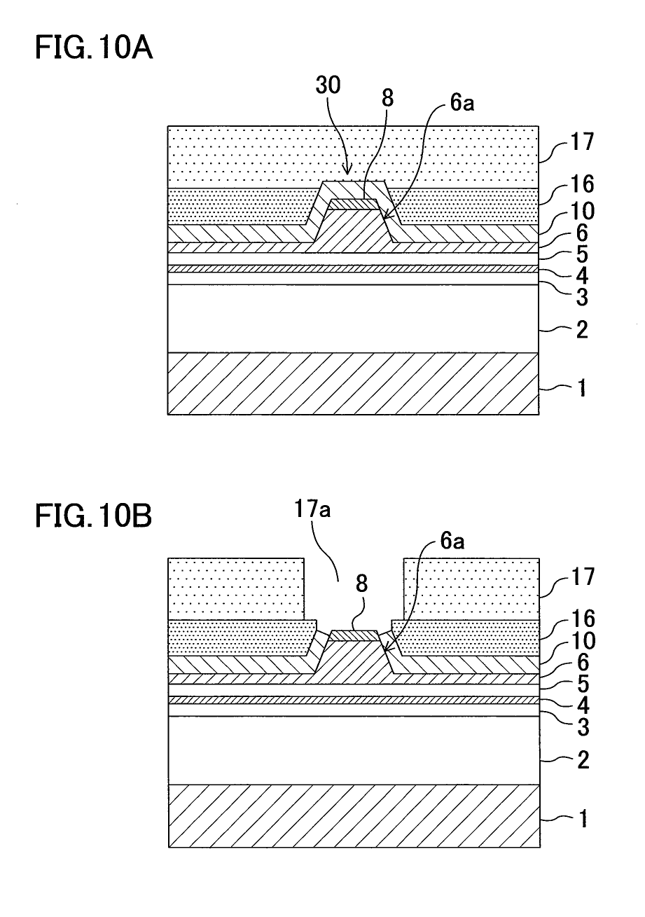

Then, as shown in FIGS. 10A and 10B, using the first resist film 16 and the second resist film 17 as a mask, the dielectric film 10 is wet-etched using, for example, buffered hydrogen fluoride. By this process, an opening is formed in the dielectric film 10 which exposes part of the contact layer 8. Specifically, the top surface of the contact layer 8 except for the no-current injection region 30 and part of the side surfaces of the contact layer 8 are exposed from the second resist film 17 for forming the P-side electrode. In this process, when the above-described pretreatment, e.g., treatment with hexamethyldisilazane (HMDS), has been performed to ensure the adhesion between the second resist film 17 and the dielectric film 10, the wet etching solution using buffered hydrogen fluoride does not penetrate an interface between the dielectric film 10 and the second resist film 17. Therefore, the etched surface of the dielectric film 10 in the no-current injection region 30 will have almost the same shape as the mask which is made of the second resist film 17 and does not have the opening 17a above the end of the ridge portion 6a. Thus, the obtained structure includes the dielectric film 10 remaining above the ridge portion 6a as the no-current injection region 30.

Next, an example (hereinafter referred to as a modified example) in which the pretreatment for ensuring the adhesion between the second resist film 17 and the dielectric film 10 is not performed before the application of the second resist film 17 will be described below.

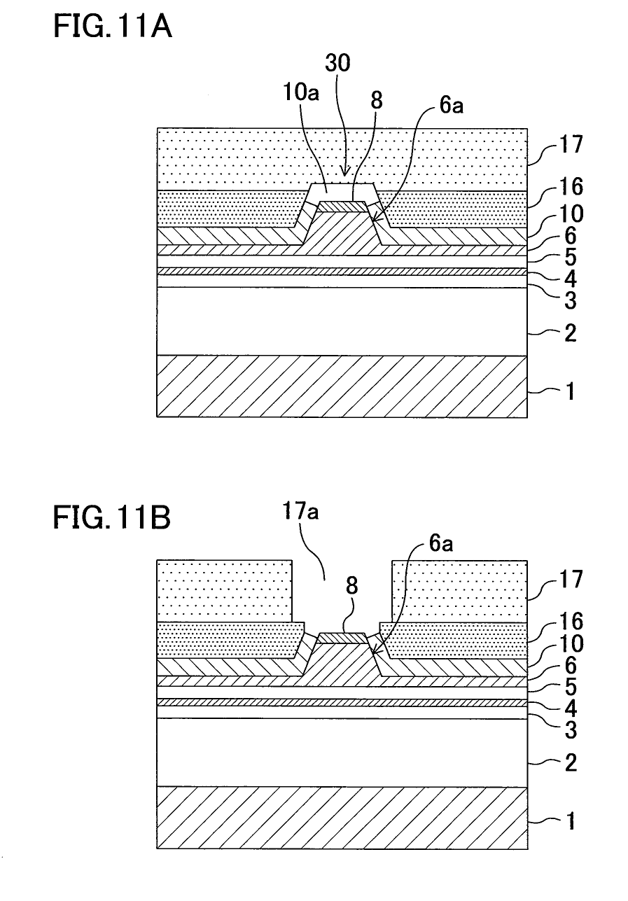

In this modified example shown in FIGS. 11A and 11B, the wet etching solution using buffered hydrogen fluoride can penetrate the interface between the dielectric film 10 and the second resist film 17. Therefore, as shown in FIG. 11A, the dielectric film 10 in the no-current injection region 30 is removed to form a hollow portion 10a.

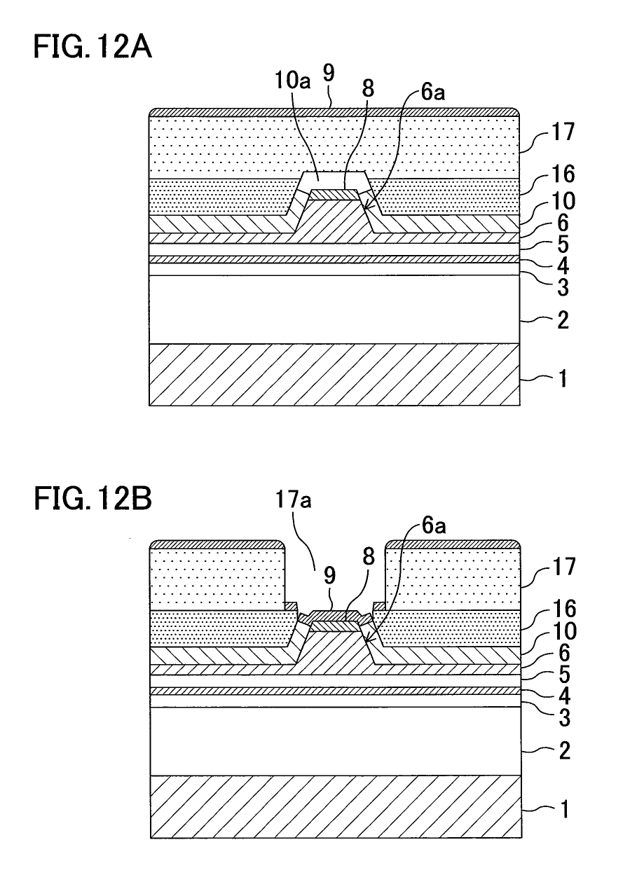

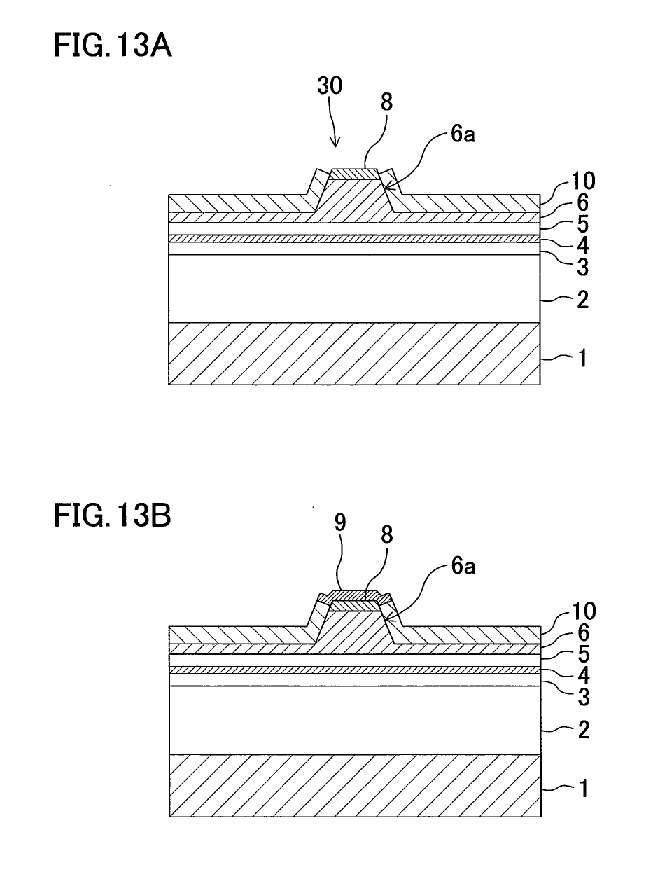

In this case, the Pd/Pt film of a predetermined thickness is deposited as shown in FIGS. 12A and 12B, and then the lifting-off is performed. In the structure thus obtained as shown in FIGS. 13A and 13B, the dielectric film 10 does not remain on the no-current injection region 30 above the ridge portion 6a as shown in FIG. 13A.

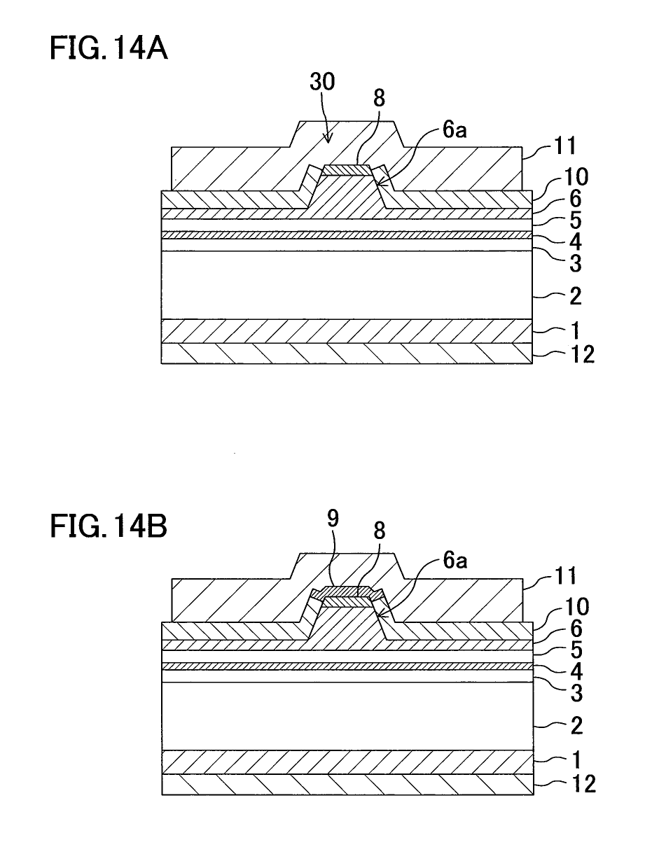

Then, as shown in FIGS. 14A and 14B, a pad electrode 11 made of a Ti/Pt/Au film is formed on the dielectric film 10 and the P-side electrode 9 by vapor deposition and lift-off. In this process, as shown in FIG. 14A, the pad electrode 11 is formed on the contact layer 8 and the dielectric film 10 at the end of the ridge portion 6a. Then, a surface (a rear surface) of the substrate 1 opposite the surface on which the n-type cladding layer 2 has been formed is polished. Then, an N-side electrode 12 is formed on the polished rear surface of the substrate 1.

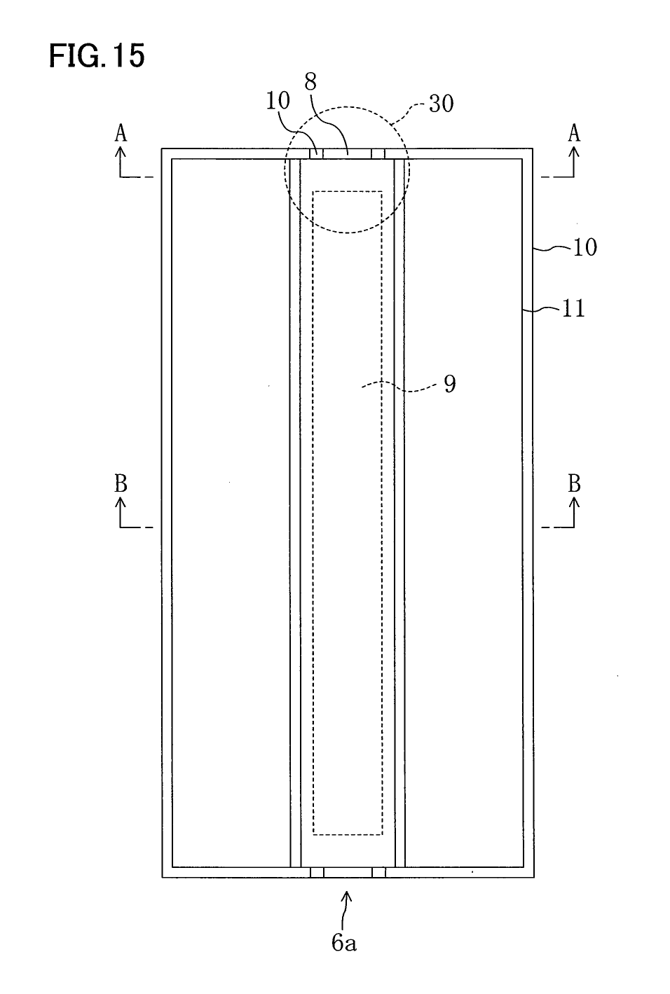

In the modified example described above, near the end face of the cavity, the dielectric film 10 does not cover the top surface of the ridge portion 6a, but the pad electrode 11 made of the Ti/Pt/Au film covers the no-current injection region 30 as shown in FIG. 14A and the plan view of FIG. 15. The Ti film which is in the pad electrode 11 and in direct contact with the contact layer 8 does not establish ohmic contact with the contact layer 8 made of p-type GaN. Thus, the no-current injection region 30 is provided.

As described above, a selection can be made between the example structure in which the dielectric film 10 covers the top surface of the ridge portion 6a in the no-current injection region 30, and the modified example structure in which the dielectric film 10 does not cover the top surface of the ridge portion 6a in the no-current injection region 30.

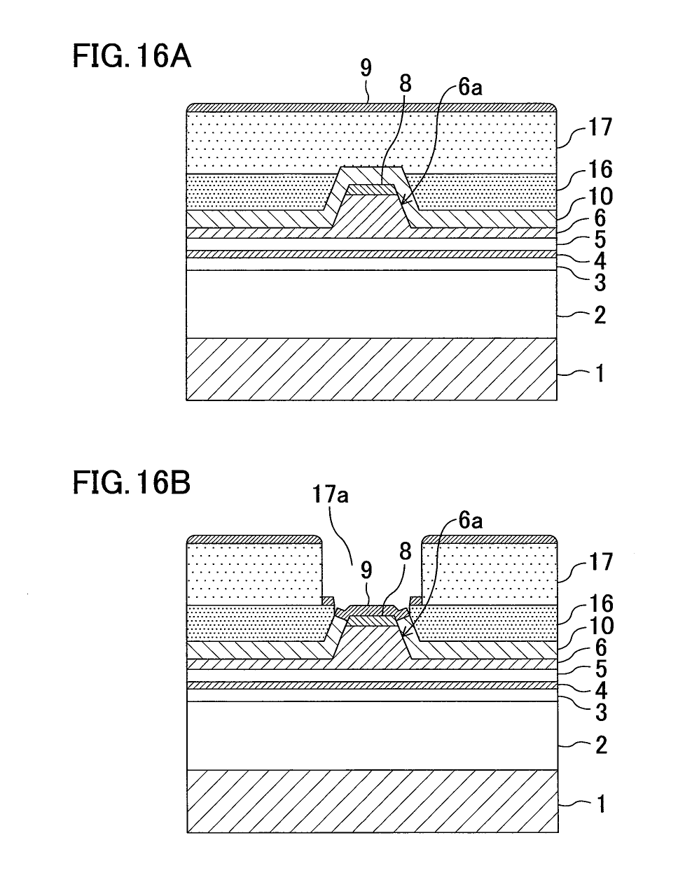

In this embodiment in which the second resist film 17 is pretreated, the Pd/Pt film of a desired thickness is vapor-deposited on the second resist film 17 to form the P-side electrode 9 on the top surface and the side surfaces of the contact layer 8 as shown in FIGS. 16A and 16B. In this process, the P-side electrode 9 is formed to extend from the top surface and the side surfaces of the contact layer 8 to the end face of the dielectric film 10 around the opening formed by etching. The Pd film forming the P-side electrode 9 is preferably 10 nm to 100 nm, both inclusive. The Pt film is preferably 10 nm or more in thickness so that it functions as a protection film for protecting the Pd film from oxidation or alteration by alloying.

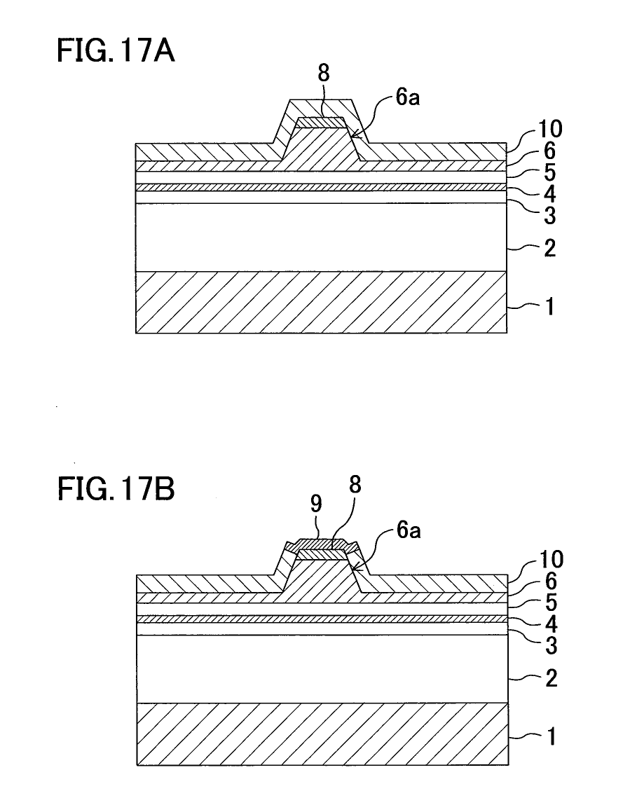

Then, as shown in FIGS. 17A and 17B, the first resist film 16, the second resist film 17 for forming the P-side electrode 9, and the P-side electrode 9 on the second resist film 17 are removed simultaneously by the lift-off process. In the method according to the present embodiment, a two-resist process is employed, i.e., the first resist film 16 is formed and patterned by a self-alignment process, i.e., the etch back process, and then the second resist film 17 having a desired opening 17a is formed on the etched back first resist film 16. This can ensure symmetry of a current blocking layer which is made of the dielectric film 10 and formed on both side surfaces of the ridge portion 6a, and symmetry of the P-side electrode 9. Further, the method of the present embodiment can implement the structure in which the no-current injection regions 30 in which the P-side electrode 9 is not formed are provided at both ends of the ridge portion 6a (cavity), and the P-side electrode 9 is provided only above the ridge portion 6a, or the structure in which the P-side electrode 9 is formed on the top surface and the side surfaces of the contact layer 8 so that the P-side electrode 9 can achieve maximum ohmic junction with the top surface of the ridge portion 6a.

As described in the present embodiment, the structure in which the dielectric film 10 remains in the no-current injection region 30, part of the dielectric film 10 formed on the both side surfaces of the ridge portion 6a, and part of the dielectric film 10 formed on the ridge portion 6a in the no-current injection region 30 are formed at the same time. Therefore, for example, in the case where a dielectric film forming a current blocking layer and another dielectric film covering the no-current injection region 30 are formed in different processes, reduction in differential quantum efficiency (Se) by the effect of impurities and the like on the interface between the dielectric films can be prevented. Moreover, the reduction in contact resistance can be prevented, and the film deposition process can be simplified by the integral formation of the dielectric film 10.

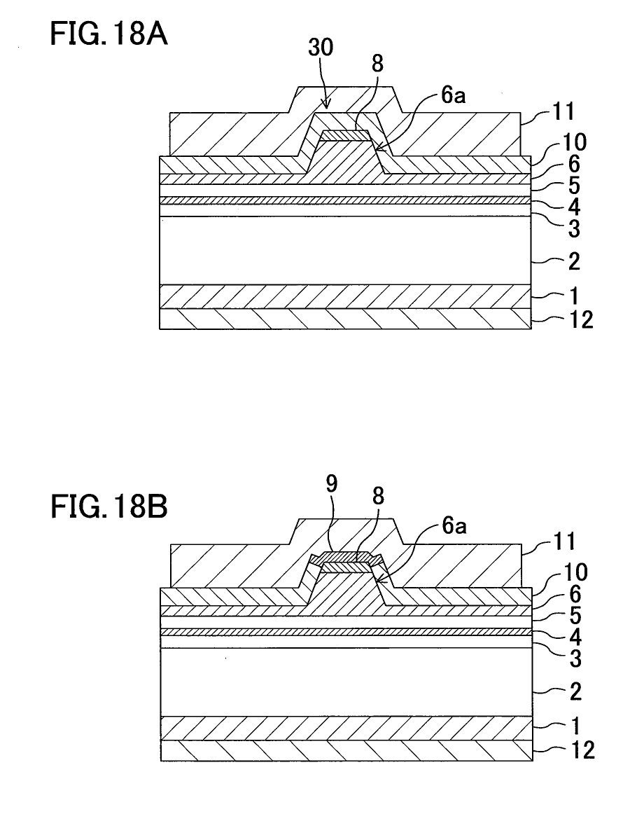

Thereafter, as shown in FIGS. 18A and 18B, a pad electrode 11 made of a Ti/Pt/Au film is formed on the dielectric film 10 and the P-side electrode 9 by vapor deposition and lift-off. Since parts of the dielectric film 10 deposited on the side surfaces of the ridge portion 6a are inclined at an angle of about 5° to 20° from a normal to the principle surface of the substrate 1 so that the dielectric film 10 on the ridge portion 6a is in the shape of a tapered mesa, the dielectric film 10 can smoothly be formed even on bottom corners of the ridge portion 6a. Therefore, the pad electrode 11 is not broken in parts thereof on the bottom corners of the ridge portion 6a. This allows the prevention of break of the device caused by electric field concentration starting from the broken part of the pad electrode 11. The pad electrode 11, which is formed on the P-side electrode 9 and includes an uppermost layer made of Au, is arranged so that an end of the pad electrode 11 near the end face of the cavity is closer to the end face of the cavity than the end of the P-side electrode 9, so as not to expose the P-side electrode 9 from the pad electrode 11. This allows the prevention of break of the device caused by electric field concentration in the P-side electrode 9. The pad electrode 11 may be formed by vapor deposition and lift-off using a resist pattern as described above, or may be formed by electrolytic plating. Subsequently, a surface (a rear surface) of the substrate 1 opposite to the surface on which the n-type cladding layer 2 has been formed is polished. Then, the N-side electrode 12 is formed on the polished rear surface of the substrate 1.

In the foregoing manner, an on-wafer process of the GaN-based semiconductor laser diode of the present embodiment is completed.

Subsequently, a wafer on which a plurality of laser diodes are formed is cleaved into a plurality of bars (laser bars), and cavities are formed in the GaN-based semiconductor laser diodes. Further, the end faces of the cleaved cavities are coated with a coating for controlling reflectance, and then the laser bars are cleaved into chips. Thus, the GaN-based semiconductor laser diodes are completed.

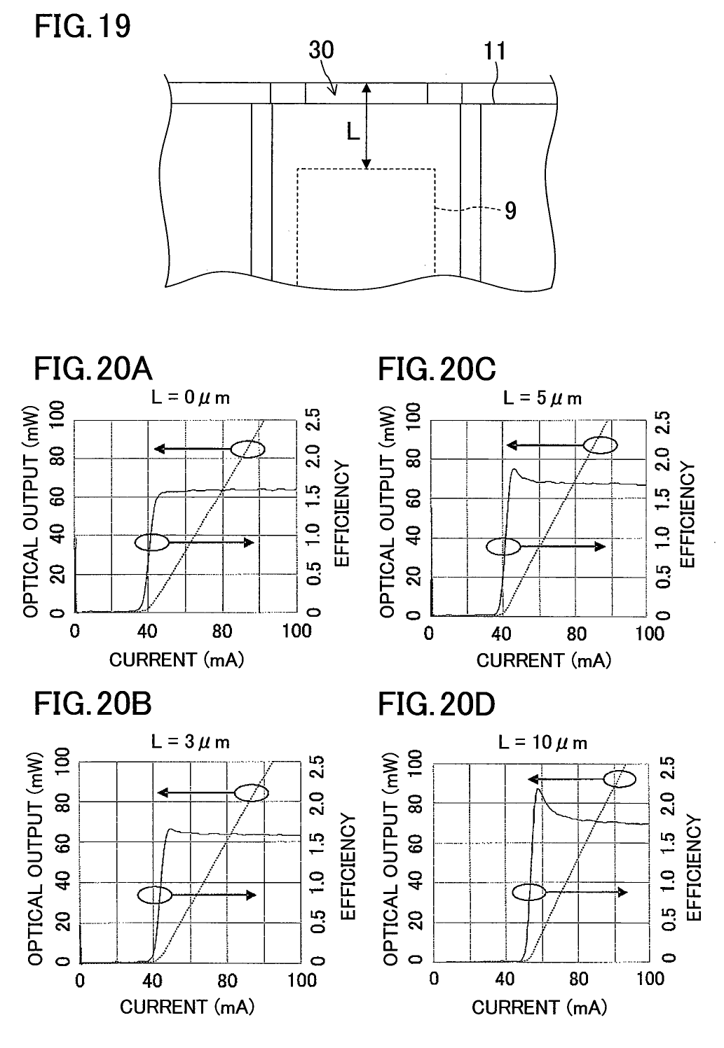

FIG. 19 shows a plan view illustrating an enlargement of the end face of the cavity of the GaN-based semiconductor laser diode according to the first example embodiment. As shown in FIG. 19, a distance between the end face of the cavity and the P-side electrode 9 in the no-current injection region 30 is defined as length L of the no-current injection region.

FIGS. 20A to 20D show current-optical output characteristics corresponding to the devices in which the length L of the no-current injection region of the GaN-based semiconductor laser diode shown in FIG. 19 is 0 μm, 3 μm, 5 μm and 10 μm, respectively. When the length L of the no-current injection region is 0 μm, it means that the device does not include the no-current injection region 30.

In comparison with the structure of FIG. 20A in which the no-current injection region 30 is not provided, efficiency in a laser oscillation region is improved as the length L of the no-current injection region increases in the order of 3 μm, 5 μm, and 10 μm, as shown in FIGS. 20B to 20D. In comparison between the structures in which the length L of the no-current injection region of 5 μm and 10 μm, respectively, discontinuous hops appear in the current-optical output characteristic in response to the increase in threshold value when the length L of the no-current injection region is 10 μm. In the structure in which the no-current injection region 30 for blocking current injection is provided near the end face of the cavity, the COD is not suppressed when the length L of the no-current injection region is too small. However, when the length L of the no-current injection region is too large, the no-current injection region 30 becomes a saturable absorber, thereby causing discontinuous hops in the current-optical output characteristic. This indicates the need of optimization of the length L of the no-current injection region.

With respect to a value of efficiency in the range where the current-optical output characteristic has linearity, it is required to control the maximum value of the efficiency near a threshold current to 0.5 W/A or less. In order to meet the requirement, the length L of the no-current injection region needs to be 10 μm or less. Specifically, when the length L exceeds 10 μm, the COD may be suppressed. However, when the laser diode is used in an optical pickup device, monitoring of the optical output cannot be performed. For this reason, the length L of the no-current injection region is set to 10 μm or less.

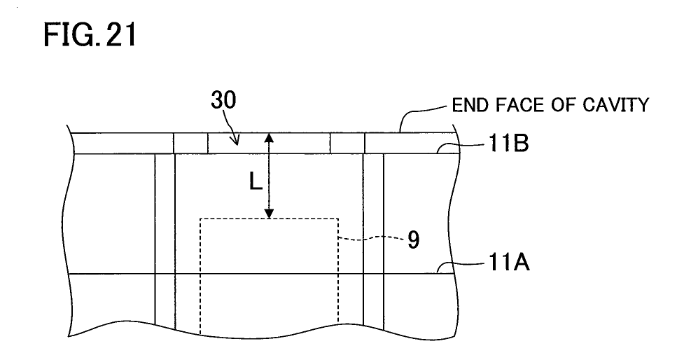

FIG. 21 shows a plan view illustrating an enlargement of the vicinity of the end face of the cavity of the GaN-based semiconductor laser diode according to the first example embodiment. FIG. 21 indicates a positional relationship between the end face of the cavity, the P-side electrode 9 and the two different positions 11A and 11B of the end of the pad electrode 11. In this figure, the length of the no-current injection region 30 is indicated by L.

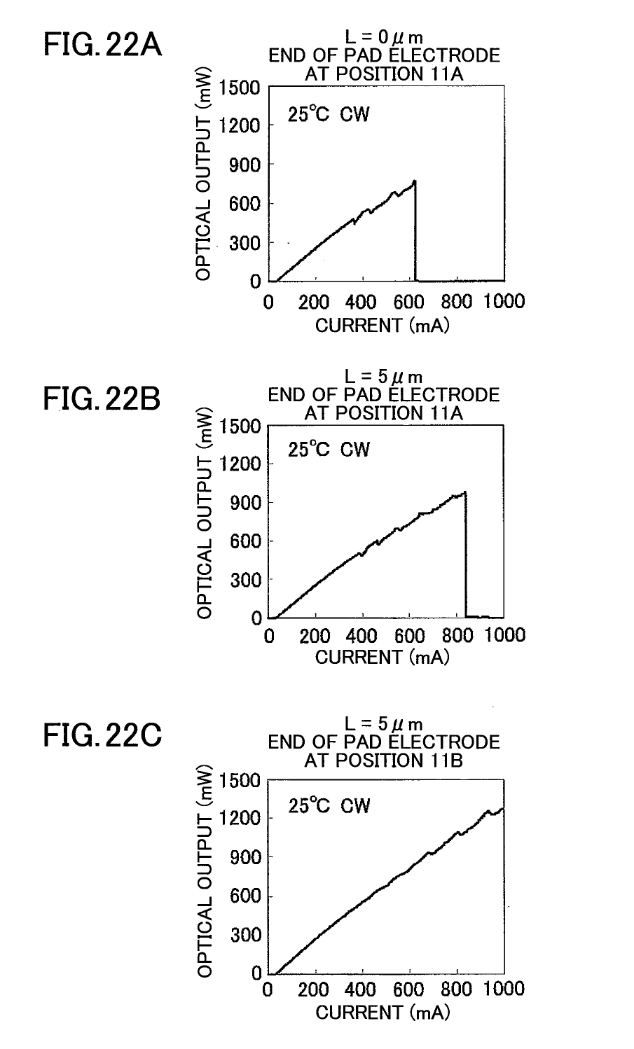

FIGS. 22A to 22C show the current-optical output characteristics during continuous wave (CW) operation at room temperature (25° C.), respectively. Specifically, FIG. 22A corresponds to the device in which the length L of the no-current injection region in which the P-side electrode exists is 0 μm and the end of the pad electrode 11 is at position 11A, FIG. 22B corresponds to the device in which the length L of the no-current injection region is 5 μm and the end of the pad electrode 11 is at position 11A, and FIG. 22C corresponds to the device in which the length L of the no-current injection region is 5 μm and the end of the pad electrode 11 is at position 11B. In FIG. 22B, the end of the P-side electrode 9 is exposed from the end of the pad electrode 11. In FIG. 22C, the end of the P-side electrode 9 is covered with the pad electrode 11.

As apparent from FIGS. 22A and 22B, when the length L of the no-current injection region is 0 μm and 5 μm, and the end of the pad electrode 11 is at position 11A, kink occurs as the optical output value reaches around 400 mA. On the other hand, FIG. 22C indicates that when the length L of the no-current injection region is 5 μm and the end of the pad electrode 11 is at position 11B, the kink does not occur until the optical output value reaches around 700 mA. In this case, it is confirmed that the level at which COD occurs is raised up to around the optical output of 1200 mW. Specifically, the structure in which the end of the P-side electrode 9 near the end face of the cavity is not exposed from the end of the pad electrode 11 makes it possible to prevent decrease of the level at which COD is caused by electric field concentration.

The GaN-based semiconductor laser diode of the first example embodiment is a semiconductor laser diode provided by the two-resist process, i.e., by forming a lower resist layer by an etch back process, and forming a desired resist mask as an upper resist layer on the lower resist layer. Therefore, the symmetry of the dielectric film 10 and that of the P-side electrode (a conductive film) 9 can be both ensured. This can avoid misalignment of a center of an optical axis of laser light from a designed value.

The laser diode of the first example embodiment includes the P-side electrode 9 formed only on a desired position of the ridge portion 6a. Therefore, as compared with the conventional structure in which the P-side electrode is formed to cover the current blocking layer made of a dielectric material such as SiO₂ or the like, the P-side electrode 9 is less likely to peel. Further, the P-side electrode 9 is formed also on the top surface and the side surfaces of the contact layer 8, and on the end face of the dielectric film 10 on the side surfaces of the ridge portion 6a. This implements maximum ohmic junction between the P-side electrode 9 and the top surface of the ridge portion 6a. As a result, the reduction in contact resistance, and the prevention of the P-side electrode 9 from coming off are both achieved.

### Second Example Embodiment

Hereinafter, a second example embodiment will be described below with reference to the drawings.

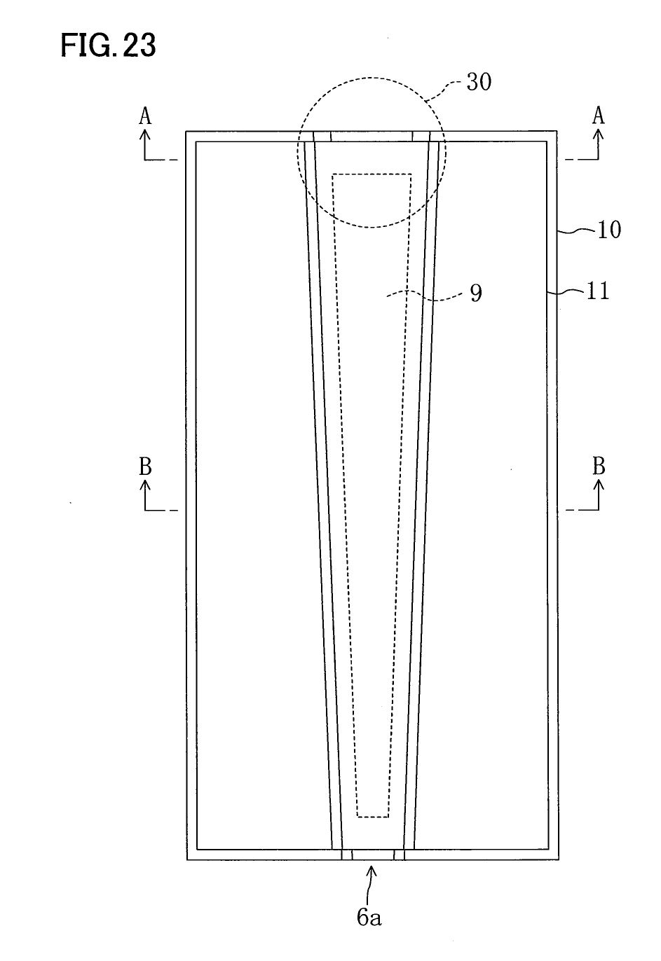

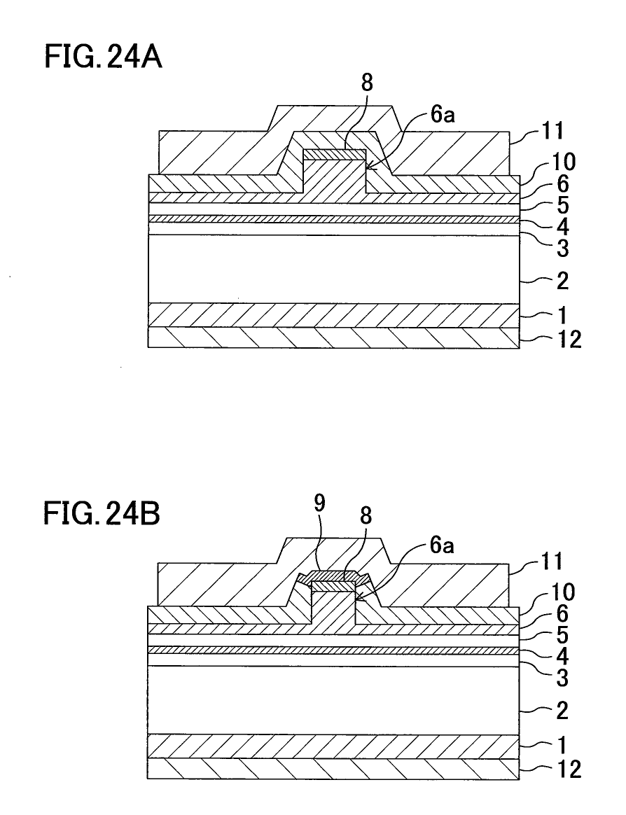

FIG. 23 shows a planar structure of a GaN-based semiconductor laser diode according to the second example embodiment. FIG. 24A shows a cross-sectional structure corresponding to the line A-A shown in FIG. 23, and FIG. 24B shows a cross-sectional structure corresponding to the line B-B shown in FIG. 23. In FIG. 23 and FIGS. 24A and 24B, the same components as those shown in FIG. 1 and FIGS. 2A and 2B are indicated by the same reference numerals to omit explanation.

As shown in FIG. 23, in the GaN-based semiconductor laser diode of the second example embodiment, the planar shape of the ridge portion 6a is varied in the direction of extension of the ridge portion 6a. Specifically, the ridge portion 6a has a small width at the front end face of the cavity, and a large width at the rear end face of the cavity, so that the ridge portion 6a is in the shape of a trapezoid when viewed in plan.

As shown in FIGS. 24A and 24B, the side surfaces of the ridge portion 6a of the second example embodiment are almost perpendicular to the principle surface of the substrate 1, i.e., they are inclined at an angle of about 0° to 5° from a normal to the principle surface of the substrate 1. However, the dielectric film 10 is in the shape of a tapered mesa when viewed in cross-section with its side surfaces inclined at an angle of about 5° to 30° from a normal to the principle surface of the substrate 1. The dielectric film 10 is about 50 nm to 400 nm in thickness.

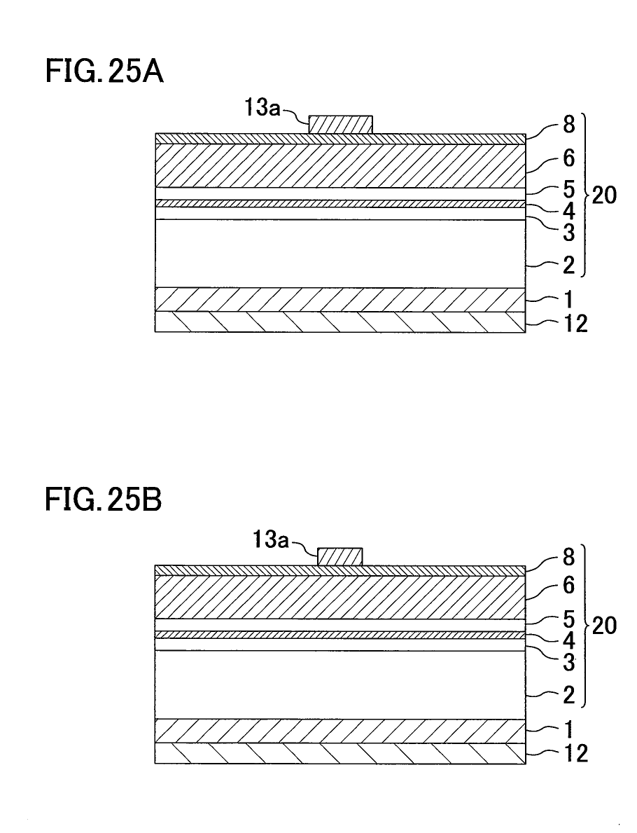

Hereinafter, a method for manufacturing the GaN-based semiconductor laser diode of the second example embodiment will be described below with reference to FIGS. 25A and 25B to FIGS. 28A and 28B. Each figure accompanied with A shows a cross-sectional structure corresponding to the line A-A shown in FIG. 23, and each figure accompanied with B shows a cross-sectional structure corresponding to the line A-A shown in FIG. 23.

First, as shown in FIGS. 25A and 25B, a semiconductor laminate 20 is formed on a substrate 1 made of n-type GaN in the same manner as in the first example embodiment, e.g., by MOCVD. Then, a mask pattern 13a which is made of SiO₂ and is trapezoidal when viewed in plan is formed on a contact layer 8.

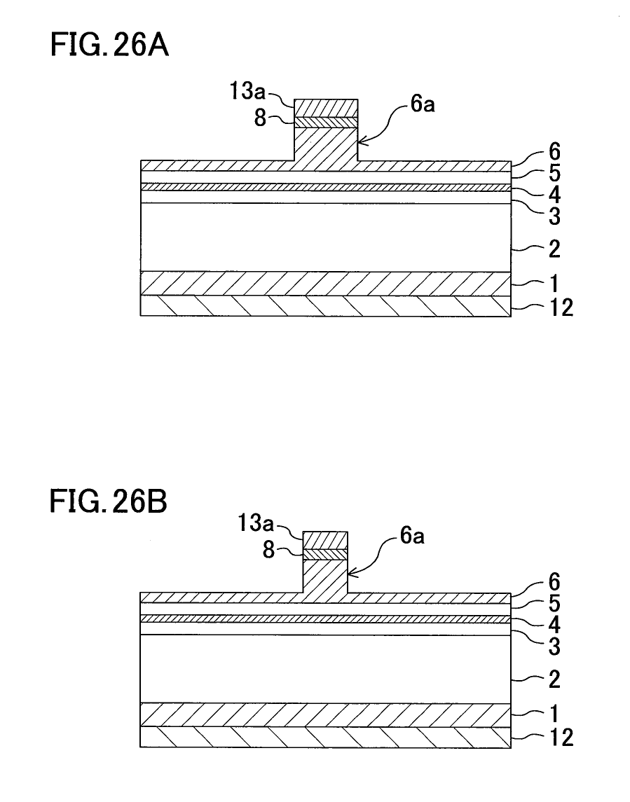

Then, as shown in FIGS. 26A and 26B, using the mask pattern 13a as a mask, the contact layer 8 and a cladding layer 6 are etched by inductively coupled plasma (ICP) etching using chlorine (Cl₂) gas to form a ridge portion 6a including the contact layer 8 and an upper portion of the cladding layer 6.

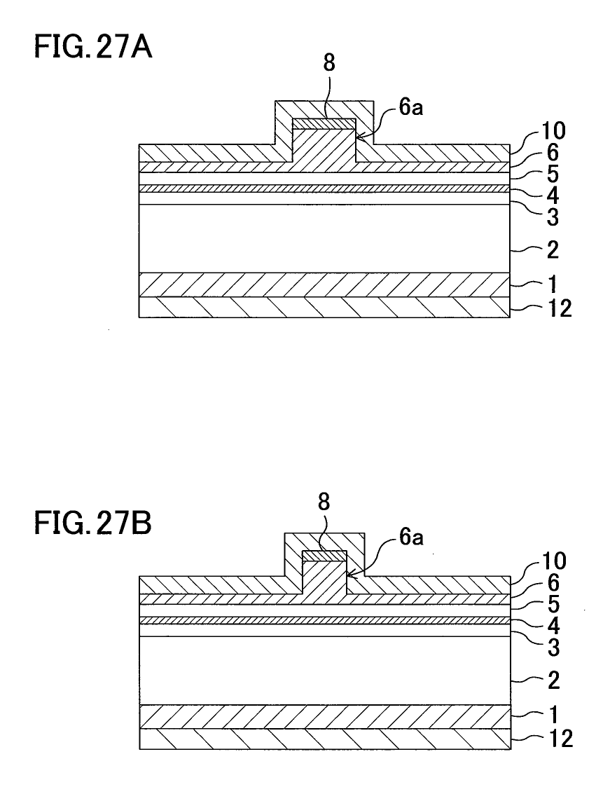

Then, as shown in FIGS. 27A and 27B, the mask pattern 13a is removed by wet etching using buffered hydrogen fluoride (BHF) or the like. This process forms an almost perpendicular ridge portion 6a with its side surfaces inclined at an angle of about 0° to 5° from a normal to the principle surface of the substrate 1. Then, a dielectric film 10 made of SiO₂ is formed by CVD to cover the entire surface of the p-type cladding layer 6 including the ridge portion 6a. In forming the dielectric film 10 by CVD, the dielectric film 10 is generally deposited also on the side surfaces of the ridge portion 6a with a thickness substantially equal to or smaller than the thickness of the dielectric film formed on the cladding layer 6 except for the ridge portion 6a. As a result, the side surfaces of the dielectric film 10 covering the ridge portion 6a are almost perpendicular to the principle surface of the substrate 1 or inverse-tapered. As described above, in the second example embodiment, the width of the ridge portion 6a in the shape of a stripe varies in the direction of extension of the ridge portion 6a.

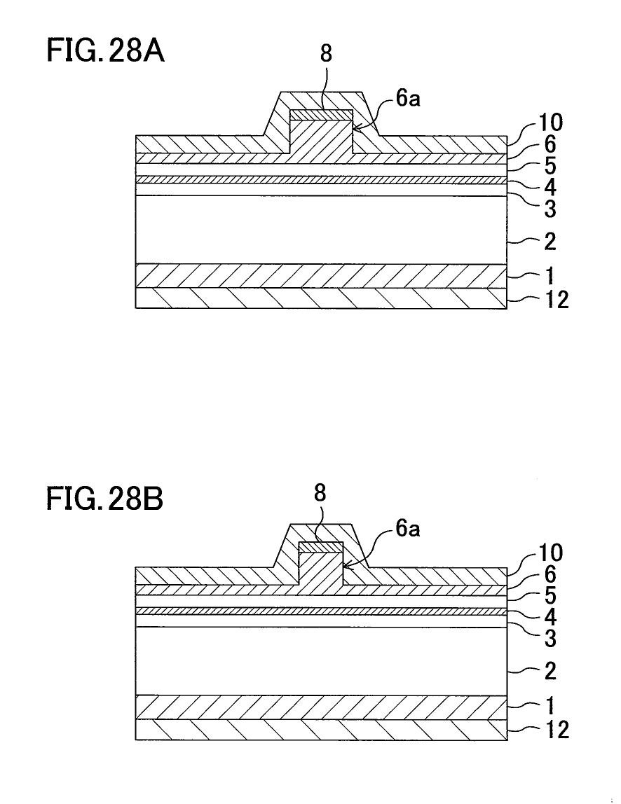

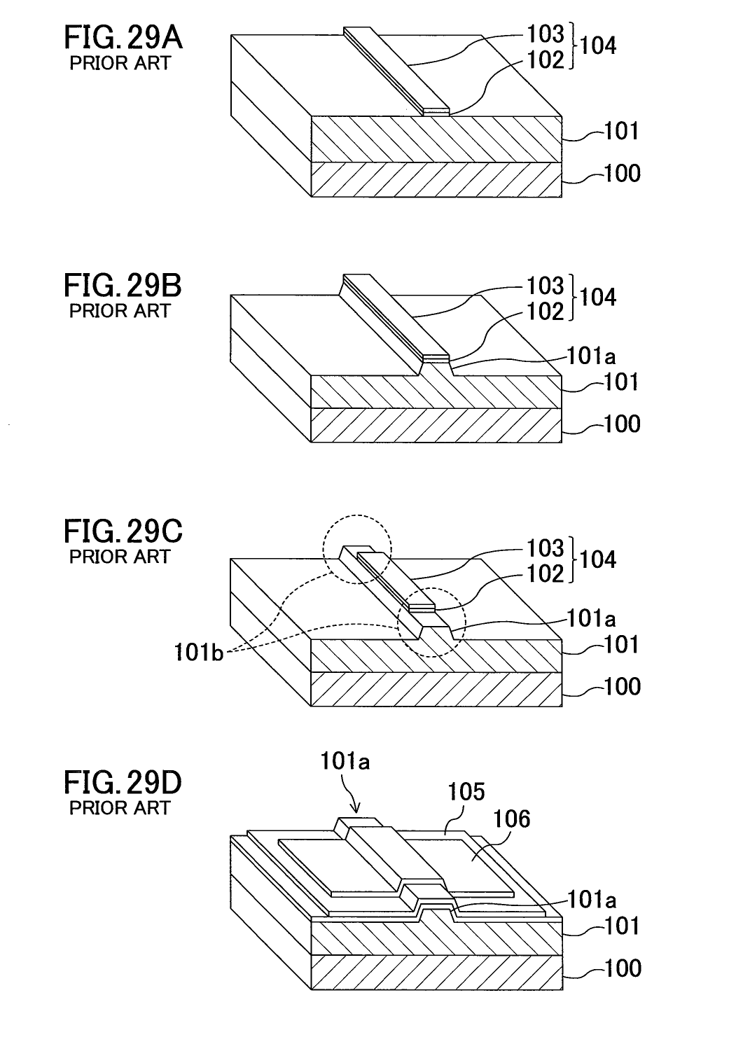

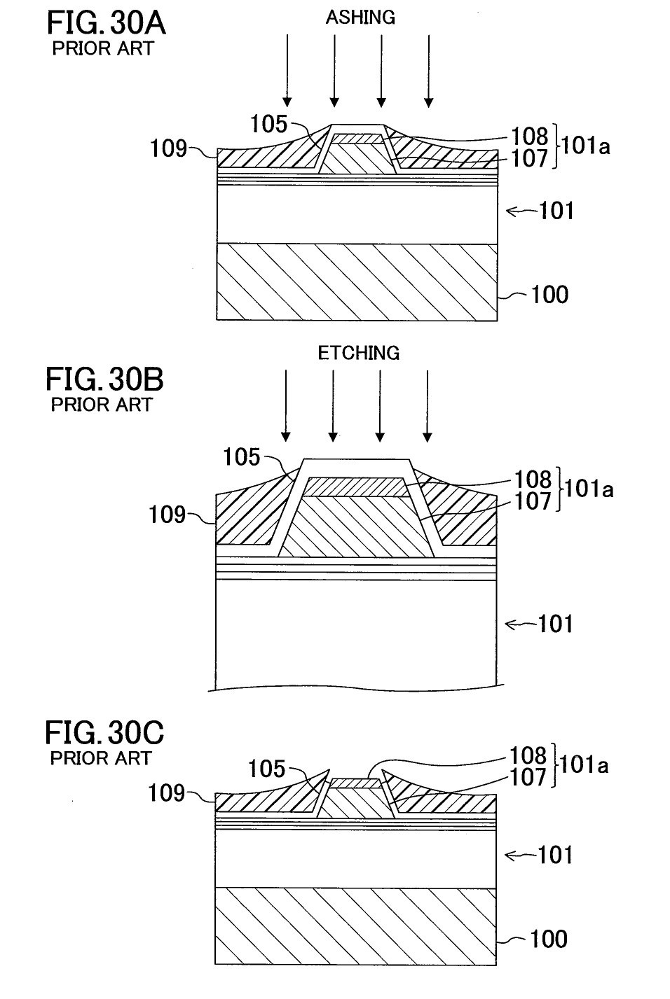

Then, as shown in FIGS. 28A and 28B, the deposited dielectric film 10 is etched by RIE using inert gas such as argon (Ar) gas or the like. As a result, parts of the dielectric film 10 formed on the side surfaces of the ridge portion 6a are tapered when viewed in cross-section. Specifically, when viewed in cross-section, the dielectric film 10 is tapered with its width increasing in a direction from the top to the bottom of the ridge portion 6a. The dielectric film 10 is about 50 nm to 400 nm in thickness. More preferably, the thickness of an upper portion of the dielectric film 10 is about 200 nm to 350 nm. The thickness of the dielectric film 10 is gradually increased toward the bottom of the ridge portion 6a. The parts of the dielectric film 10 formed on the side surfaces of the ridge portion 6a are inclined at an angle of about 5° to 30° from a direction perpendicular to the principle surface of the substrate 1, so that the dielectric film 10 is in the shape of a tapered mesa when viewed in cross-section without exposing the ridge portion 6a.

Thereafter, in the same manner as in the first example embodiment, a P-side electrode 9 is selectively formed on part of the dielectric film 10 on the top surface of the ridge portion 6a using two resist films. Then, a pad electrode 11 is formed on the dielectric film 10 and the P-side electrode 9. In the second example embodiment, the pad electrode 11 including an uppermost layer made of Au can be formed smoothly on the bottom corners of the ridge portion 6a, even when the side surfaces of the ridge portion 6a are almost perpendicular to the principle surface of the substrate 1, or the width of the ridge portion 6a varies in the direction of extension of the ridge portion 6a when viewed in plan. Thus, the pad electrode 11 does not break at the bottom corners of the ridge portion 6a, and therefore, break of the device caused by electric field concentration starting from the break of the pad electrode 11 can be prevented.

As described with reference to FIG. 21, the P-side electrode 9 and the pad electrode 11 formed on the P-side electrode 9 are preferably arranged so that the distance between the P-side electrode 9 and the end face of the cavity is larger than the distance between the pad electrode 11 and the end face of the cavity so as not to expose the P-side electrode 9 from the end of the pad electrode 11. This allows the prevention of break of the device caused by electric field concentration in the P-side electrode 9.

In the second example embodiment, the side surfaces of the ridge portion 6a are almost perpendicular to the principle surface of the substrate 1. When the width of the ridge portion 6a varies in the direction of extension of the ridge portion 6a (the ridge portion 6a is in the shape of a tapered stripe when viewed in plan), this makes it possible to set the width of the rear end of the ridge portion 6a larger than the width of the front end of the ridge portion 6a. As a result, the contact resistance between the contact layer 8 and the P-side electrode 9 can be reduced. Since this allows the reduction in operating voltage of the laser diode, the tapered stripe structure is a suitable structure for the high power GaN-based semiconductor laser diode.

As described above, in the method for manufacturing the GaN-based laser diode according to the embodiments, the so-called etch back process, which is a self alignment process, is used, and the two-resist process of forming a desired mask as an upper resist layer is employed. This can ensure symmetry of the dielectric film 10 and that of the P-side electrode 9 formed on the ridge portion 6a. Further, with the provision of the no-current injection region 30 in which the P-side electrode 9 is not formed on part of the ridge portion 6a at the end of the cavity, misalignment of a center of an optical axis can be avoided. This allows implementation of a high level of COD.

The second example embodiment further allows the prevention of peeling of the electrode in cleaving the wafer on which the laser structures have been formed, and peeling of the contact layer 8 during the manufacturing process. This can prevent the increase in contact resistance, and prevent problems in a laser characteristic, such as discontinuous hops that appear in the current-optical output characteristic.

The P-side electrode 9 is formed only on a predetermined region on the ridge portion 6a. Therefore, as compared with the structure in which the P-side electrode covers a current blocking layer made of a SiO₂ dielectric film, the peeling of the electrode is less likely to occur. For example, metal which establishes good ohmic contact with p-type GaN, such as palladium (Pd) and nickel (Ni), is particularly poor in adhesion to SiO₂. In this point of view, the structure in which the P-side electrode 9 made of Pd or Ni is formed only on the ridge portion 6a is particularly advantageous in preventing the peeling of the electrode.

The P-side electrode 9 is formed also on the top surface and the side surfaces of the contact layer 8, so that the ohmic junction between the P-side electrode 9 and the top surface of the ridge portion 6a is maximized. This can implement both of the reduction in contact resistance and the prevention of peeling of the electrode.

Further, the no-current injection region 30 is integral with the dielectric film 10 serving as a current blocking layer. This can prevent the reduction in differential quantum efficiency (Se) due to the increase in loss caused by current leakage via impurities at the interface between the dielectric film 10 and the contact layer 8. Simultaneously, this can avoid the surface of the contact layer 8, which is instable to alkaline substances and resist materials, from unwanted contact with the resist material during the manufacturing process. Thus, the increase in contact resistance between the contact layer 8 and the P-side electrode 9 can be prevented.

As described above, the example semiconductor light emitting device is advantageous in FFP (Far Field Pattern) characteristic and reliability, and therefore is useful as laser light sources for optical pickup devices in high density optical disc systems. Further, since the semiconductor light emitting device can be manufactured with high yield, the example semiconductor light emitting device are also applicable to other fields using the semiconductor light emitting device as a light source.

What is claimed is:

1. A semiconductor light emitting device comprising:
a semiconductor laminate which includes at least a first cladding layer of a first conductivity type, an active layer, a second cladding layer of a second conductivity type, and a contact layer of the second conductivity type stacked in this order on a semiconductor substrate, the semiconductor laminate having a ridge portion including the second cladding layer and the contact layer shaped into a stripe;
a dielectric film which is formed on the second cladding layer to cover the ridge portion and has an opening selectively exposing a top of the ridge portion; and
a first electrode which is formed on the top of the ridge portion and is in contact with a top surface and a side surface of the contact layer exposed from the dielectric film, wherein
the dielectric film includes a no-current injection region which covers at least one of ends of the ridge portion near end faces of a cavity so as to block current injection into the active layer, and
the no-current injection region of the dielectric film is in contact with the contact layer.

2. The semiconductor light emitting device of claim 1, wherein
the first electrode is in contact with the entire top surface and both side surfaces of the contact layer exposed from the dielectric film.

3. The semiconductor light emitting device of claim 1, wherein
a width of the ridge portion varies in a direction of extension of the ridge portion.

4. The semiconductor light emitting device of claim 1, wherein
the semiconductor substrate and the semiconductor laminate are made of a group III-V nitride compound semiconductor represented by InₓAl_{y}Ga_{1-x-y}N (wherein 0≦x≦1, 0≦y≦1, x+y≦1).

5. The semiconductor light emitting device of claim 4, wherein
the first electrode contains nickel or palladium in part thereof in contact with the contact layer.

6. The semiconductor light emitting device of claim 1, further comprising:
a second electrode formed on the dielectric film and the first electrode, wherein
the second electrode is formed so that an end of the second electrode near the end face of the cavity is positioned above the no-current injection region.

7. The semiconductor light emitting device of claim 6, wherein
a width of the end of the second electrode near the end face of the cavity is larger than the width of the ridge portion.

8. The semiconductor light emitting device of claim 1, wherein
side surfaces of the ridge portion are inclined so that the ridge portion has a trapezoidal cross section with its width increasing in a direction from the top to the bottom of the ridge portion.

9. The semiconductor light emitting device of claim 1, wherein
the dielectric film is formed so that a distance between outer surfaces of parts of the dielectric film covering the side surfaces of the ridge portion increases in a direction from the top to the bottom of the ridge portion.

10. The semiconductor light emitting device of claim 1, wherein
a distance between an end of the first electrode near the end face of the cavity and the end face of the cavity is 3 μm to 10 μm, both inclusive.

11. A method for manufacturing a semiconductor light emitting device comprising:
stacking at least an n-type cladding layer, an active layer, a p-type cladding layer and a p-type contact layer, which are semiconductor layers, in this order on a semiconductor substrate to form a semiconductor laminate;
etching the p-type cladding layer and the p-type contact layer to form a ridge portion in the shape of a stripe;
forming a dielectric film on the semiconductor laminate to cover the ridge portion;
forming a first resist film on the dielectric film, and etching back the first resist film to expose part of the dielectric film above the ridge portion from the first resist film;
inactivating the first resist film;
forming a second resist film on the first resist film including the part of the dielectric film above the ridge portion;
performing light exposure and development on the second resist film to form an opening in the second resist film which exposes the part of the dielectric film above the ridge portion, while at least one of ends of the dielectric film near the end faces of a cavity remains covered;
etching the dielectric film using the first resist film and the second resist film as a mask to selectively expose a top of the ridge portion from the dielectric film;
forming a first conductive film on the first resist film and the second resist film including the exposed top of the ridge portion;
removing the first resist film and the second resist film to selectively form a first electrode made of the first conductive film on the ridge portion; and
forming a second conductive film on the first electrode, and patterning the second conductive film to form a second electrode made of the second conductive film.

12. The method for manufacturing the semiconductor light emitting device of claim 11, wherein in the forming the ridge portion, the ridge portion is formed so that its width increases in a direction from the top to the bottom of the ridge portion.

13. The method for manufacturing the semiconductor light emitting device of claim 11, wherein in the forming of the dielectric film, the dielectric film is formed so that a distance between outer surfaces of parts of the dielectric film covering the side surfaces of the ridge portion increases in a direction from the top to the bottom of the ridge portion.

14. The method for manufacturing the semiconductor light emitting device of claim 13, wherein
the increasing the distance between the outer surfaces of the parts of the dielectric film covering the side surfaces of the ridge portions in the direction from the top to the bottom of the ridge portion is implemented by dry etching using inert gas.

15. The method for manufacturing the semiconductor light emitting device of claim 14, wherein
the inert gas is argon.

16. The method for manufacturing the semiconductor light emitting device of claim 11, further comprising:
exposing the dielectric film to an agent which improves adhesion between the dielectric film and the second resist film between the inactivating the first resist film and the forming the second resist film.

17. The method for manufacturing the semiconductor light emitting device of claim 11, wherein
the exposing the ridge portion from the dielectric film is implemented by wet etching.

18. The method for manufacturing the semiconductor light emitting device of claim 11, wherein
the inactivating the first resist film is implemented by UV irradiation or baking at a temperature of 150° C. or higher.

19. The method for manufacturing the semiconductor light emitting device of claim 11, wherein
the semiconductor substrate and the semiconductor laminate are made of a group III-V nitride compound semiconductor represented by InₓAl_{y}Ga_{1-x-y}N (wherein 0≦x≦1, 0y≦≦1, x+y≦1).
